(19) United States
(12) Patent Application Publication
(10) Pub. No.: US 2026/0026142 A1
(43) Pub. Date: Jan. 22, 2026

(54) Light-Emitting Device, Light-Emitting Substrate, Backlight Module, and Display Apparatus

(71) Applicants: BEIJING BOE TECHNOLOGY DEVELOPMENT CO., LTD., Beijing (CN); BOE TECHNOLOGY GROUP CO., LTD., Chaoyang District, Beijing (CN)

(72) Inventors: Liuqing Li, Beijing (CN); Xinhong Lu, Beijing (CN); Shuilang Dong, Beijing (CN); Zhanfeng Cao, Beijing (CN); Guangcai Yuan, Beijing (CN); Ying Zhou, Beijing (CN); Jingshang Zhou, Beijing (CN); Shaopeng Yang, Beijing (CN); Guoteng Li, Beijing (CN)

(21) Appl. No.: 18/852,887

(22) PCT Filed: Oct. 31, 2023
(86) PCT No.: PCT/CN2023/128731

§ 371 Date: Sep. 30, 2024

(51) Int. Cl. H10H 20/857; H01L 25/075; H10H 20/831; H10H 20/841; H10H 20/853

(52) U.S. Cl. CPC H10H 20/857; H01L 25/0753; H10H 20/831; H10H 20/841; H10H 20/853

(57) ABSTRACT

A light-emitting device includes a first electrode, a light-emitting stacked layer, a second electrode and a passivation layer. The light-emitting stacked layer is connected to the first electrode. The passivation layer includes a first passivation portion and a second passivation portion. The first passivation portion covers a surface of the light-emitting stacked layer away from the first electrode. The first passivation portion is provided therein with a first via hole. The second electrode is connected to the light-emitting stacked layer through the first via hole. The second passivation portion covers a sidewall of the light-emitting stacked layer and extends to a side of the light-emitting stacked layer away from the second electrode. A distance between a portion of the second passivation portion exceeding the light-emitting stacked layer and the light-emitting stacked layer is greater than a thickness of the first electrode.

### CROSS-REFERENCE TO RELATED APPLICATION

This application is the United States national phase of International Patent Application No. PCT/CN2023/128731, filed Oct. 31, 2023, the disclosure of which is hereby incorporated by reference in its entirety.

### BACKGROUND OF THE INVENTION

### Field of the Invention

The present disclosure relates to the field of display technologies, and in particular, to a light-emitting device, a method for manufacturing a light-emitting device, a light-emitting substrate, a method for manufacturing a light-emitting substrate, a backlight module, and a display apparatus.

### Description of Related Art

With the development of light-emitting diode technologies, light-emitting substrates using light-emitting diodes (LEDs) with mini scale and even micro scale have been widely used. Therefore, a picture contrast of a product (e.g., a liquid crystal display (LCD)) using the light-emitting substrate may reach a level of an organic light-emitting diode (OLED) display product, and the product may retain the technical advantages of the liquid crystal display (LCD). As a result, the display effect of the picture may be improved, which may provide a good visual experience for users.

### SUMMARY OF THE INVENTION

In an aspect, a light-emitting device is provided. The light-emitting device includes a first electrode, a light-emitting stacked layer, a second electrode and a passivation layer. The light-emitting stacked layer is disposed on a side of the first electrode and connected to the first electrode. The second electrode is disposed on a side of the light-emitting stacked layer away from the first electrode. The second electrode is configured to be connected to a driving backplane. The passivation layer includes a first passivation portion and a second passivation portion. The first passivation portion covers a surface of the light-emitting stacked layer away from the first electrode; the first passivation portion is provided therein with a first via hole, and the second electrode is connected to the light-emitting stacked layer through the first via hole; the second passivation portion covers a sidewall of the light-emitting stacked layer and extends to a side of the light-emitting stacked layer away from the second electrode; a distance between a portion of the second passivation portion exceeding the light-emitting stacked layer and the light-emitting stacked layer is greater than a thickness of the first electrode.

In some embodiments, the second passivation portion covers the sidewall of the light-emitting stacked layer and a sidewall of the first electrode, and extends to the side of the light-emitting stacked layer away from the second electrode.

In some embodiments, the light-emitting device further includes a connection electrode, and the connection electrode is disposed on a side of the first electrode away from the second electrode. The connection electrode covers the first electrode and extends to a surface of the second passivation portion away from the first passivation portion.

In some embodiments, boundaries of two surfaces, facing away from each other, of the light-emitting stacked layer and the first electrode are connected to form a slope surface, and a slope angle of the slope surface is greater than or equal to 60°.

In some embodiments, the light-emitting device further includes a hard mask layer, and the hard mask layer is disposed between a surface of the light-emitting stacked layer away from the first electrode and the passivation layer. The hard mask layer is provided therein with a second via hole, and the second electrode is connected to the light-emitting stacked layer through the first via hole and the second via hole.

In some embodiments, boundaries of two surfaces, facing away from each other, of the light-emitting stacked layer and the first electrode are connected to form a slope surface, and a slope angle of the slope surface is greater than or equal to 80°.

In some embodiments, a thickness of the first electrode is in a range of 1000 Å to 6000 Å.

In some embodiments, the sidewall of the light-emitting stacked layer is of a stepped structure; and in a direction from the second electrode to the first electrode, a circumferential boundary of the light-emitting stacked layer is indented in a stepped manner.

In some embodiments, the light-emitting device further includes a reflective layer, and the reflective layer is disposed on a side of the passivation layer away from the light-emitting stacked layer.

In another aspect, a light-emitting device is provided. The light-emitting device includes a first electrode, a light-emitting stacked layer, a second electrode and a passivation layer. The light-emitting stacked layer is disposed on the first electrode and connected to the first electrode. A boundary of the light-emitting stacked layer is retracted relative to a boundary of the first electrode. The second electrode is disposed on a side of the light-emitting stacked layer away from the first electrode, and the second electrode is configured to be connected to a driving backplane. The passivation layer includes a first passivation portion and a second passivation portion that are connected. The first passivation portion covers a surface of the light-emitting stacked layer away from the first electrode; the first passivation portion is provided therein with a first via hole, and the second electrode is connected to the light-emitting stacked layer through the first via hole; the second passivation portion covers a sidewall of the light-emitting stacked layer; and at least part of an edge of the first electrode exceeds the second passivation portion.

In some embodiments, the second passivation portion is located on an edge portion of the first electrode that exceeds the light-emitting stacked layer, and an outer boundary of the second passivation portion is retracted relative to the boundary of the first electrode.

In some embodiments, the second passivation portion includes a first sub-portion and a second sub-portion that are connected along a circumferential direction of the light-emitting stacked layer; the first sub-portion covers a part of the sidewall of the light-emitting stacked layer and a part of a sidewall of the first electrode; the second sub-portion covers another part of the sidewall of the light-emitting stacked layer and is located on an edge portion of the first electrode that exceeds the light-emitting stacked layer; and the edge portion of the first electrode corresponding to the second sub-portion exceeds the second passivation portion.

In yet another aspect, a light-emitting device is provided. The light-emitting device includes a first electrode, a light-emitting stacked layer, a second electrode and a passivation layer. The first electrode includes an electrode body and a plurality of bonding protrusions, and the plurality of bonding protrusions are arranged at intervals on a side of the electrode body. The light-emitting stacked layer is disposed on a side of the electrode body away from the bonding protrusions and connected to the electrode body. The second electrode is disposed on a side of the light-emitting stacked layer away from the first electrode, and the second electrode is configured to be connected to a driving backplane. The passivation layer includes a first passivation portion and a second passivation portion that are connected; the first passivation portion covers a surface of the light-emitting stacked layer away from the first electrode; the first passivation portion is provided therein with a first via hole, and the second electrode is connected to the light-emitting stacked layer through the first via hole; and the second passivation portion covers at least part of sidewalls of the light-emitting stacked layer and the electrode body.

In some embodiments, the plurality of bonding protrusions are arranged in an array.

In yet another aspect, a light-emitting substrate is provided. The light-emitting substrate includes a plurality of light-emitting devices as described in any of the above embodiments and a driving backplane being provided therein with a plurality of third electrodes. The second electrode of the light-emitting device is connected to a third electrode of the driving backplane.

In some embodiments, among at least two adjacent light-emitting devices, one is a first light-emitting device and another is a second light-emitting device. The passivation layer of the first light-emitting device includes a first passivation portion and a second passivation portion that are connected, the second passivation portion covers a sidewall of the light-emitting stacked layer; and at least part of an edge of the first electrode exceeds the second passivation portion. The passivation layer of the second light-emitting device includes a first passivation portion and a second passivation portion that are connected, the second passivation portion includes a first sub-portion and a second sub-portion that are connected along a circumferential direction of the light-emitting stacked layer, the first sub-portion covers a part of the sidewall of the light-emitting stacked layer and a part of a sidewall of the first electrode, the second sub-portion covers another part of the sidewall of the light-emitting stacked layer and is located on an edge portion of the first electrode that exceeds the light-emitting stacked layer, and the edge portion of the first electrode corresponding to the second sub-portion exceeds the second passivation portion.

Each of the first light-emitting device and the second light-emitting device includes a reflective layer, and the reflective layer is disposed on a side of the passivation layer away from the light-emitting stacked layer; a first sub-portion of the second light-emitting device faces the first light-emitting device; the reflective layer of the second light-emitting device covers the first sub-portion, and is connected to a portion of the first electrode of the first light-emitting device that exceeds the passivation layer.

In some embodiments, among at least two adjacent light-emitting devices, one is a third light-emitting device and another is a fourth light-emitting device. The passivation layer of the third light-emitting device includes a first passivation portion and a second passivation portion that are connected, the second passivation portion covers a sidewall of the light-emitting stacked layer; and at least part of an edge of the first electrode exceeds the second passivation portion. The passivation layer of the fourth light-emitting device includes a first passivation portion and a second passivation portion that are connected, the second passivation portion includes a first sub-portion and a second sub-portion that are connected along a circumferential direction of the light-emitting stacked layer, the first sub-portion covers a part of the sidewall of the light-emitting stacked layer and a part of a sidewall of the first electrode, the second sub-portion covers another part of the sidewall of the light-emitting stacked layer and is located on an edge portion of the first electrode that exceeds the light-emitting stacked layer, and the edge portion of the first electrode corresponding to the second sub-portion exceeds the second passivation portion.

The light-emitting substrate further includes a first planarization layer, and the first planarization layer is disposed on a side of the second electrode close to the light-emitting stacked layer of the light-emitting device; the first planarization layer is provided therein with a third via hole; and the second electrode of the third light-emitting device is connected to a portion of the first electrode of the fourth light-emitting device that exceeds the passivation layer through the third via hole.

In some embodiments, the light-emitting substrate has a light-emitting region and a peripheral region, and the light-emitting substrate further includes a planar electrode, a plurality of encapsulation portions, and an auxiliary electrode.

The planar electrode covers the light-emitting region and extends to the peripheral region, and the planar electrode is disposed on a side of the light-emitting device away from the driving backplane and connected to the first electrode of the light-emitting device. The plurality of encapsulation portions are arranged at intervals on a side of the planar electrode away from the driving backplane, and an orthogonal projection of a single light-emitting device on the driving backplane is located within an orthogonal projection of a single encapsulation portion on the driving backplane. The auxiliary electrode is disposed on the side of the planar electrode away from the driving backplane and connected to the planar electrode, the auxiliary electrode is provided therein with a plurality of openings, a single opening exposes a single light-emitting device, and a shape of an orthogonal projection of the opening on the driving backplane is the same as a shape of the orthogonal projection of the light-emitting device on the driving backplane.

In yet another aspect, a backlight module is provided. The backlight module includes: the light-emitting substrate as described in any of the above embodiments and a plurality of optical films. The light-emitting substrate has a light-exit side and a non-light-exit side that are opposite to each other, and the plurality of optical films are disposed on the light-exit side of the light-emitting substrate.

In yet another aspect, a display apparatus is provided. The display apparatus includes: the backlight module as described in the above embodiments, and a display panel disposed on a side of the plurality of optical films in the backlight module away from the light-emitting substrate.

In yet another aspect, a method for manufacturing a light-emitting device is provided. The method includes: forming a transfer epitaxial wafer, wherein the transfer epitaxial wafer includes a first substrate, a light-emitting stacked layer and a first electrode, and the first electrode and the light-emitting stacked layer are sequentially stacked on the first substrate; connecting first electrodes of a plurality of transfer epitaxial wafers to a second substrate, wherein the plurality of transfer epitaxial wafers are arranged at intervals on the second substrate; removing first substrates of the transfer epitaxial wafers; patterning the transfer epitaxial wafers, so that each transfer epitaxial wafer is divided into a plurality of epitaxial sub-wafers, each epitaxial sub-wafer includes a light-emitting stacked layer and a first electrode; sequentially forming passivation layers and second electrodes, wherein a passivation layer includes a first passivation portion and a second passivation portion; the first passivation portion covers a surface of the light-emitting stacked layer away from the first electrode; the first passivation portion is provided therein with a first via hole, and a second electrode is connected to the light-emitting stacked layer through the first via hole; and removing the second substrate.

In some embodiments, connecting the first electrodes of the plurality of transfer epitaxial wafers to the second substrate, includes: forming a plurality of bonding protrusions on the second substrate; and bonding a first electrode of each transfer epitaxial wafer to at least two bonding protrusions.

In some embodiments, connecting the first electrodes of the plurality of transfer epitaxial wafers to the second substrate, includes: forming a second adhesive layer on the second substrate; and adhering the first electrodes of the plurality of transfer epitaxial wafers to the second adhesive layer.

In some embodiments, connecting the first electrodes of the plurality of transfer epitaxial wafers to the second substrate, includes: forming a third adhesive layer and a bonding layer on the second substrate, wherein a thickness of the third adhesive layer is in a range of 1000 Å to 5000 Å; and bonding the first electrodes of the plurality of transfer epitaxial wafers to the bonding layer.

In some embodiments, patterning the transfer epitaxial wafers includes: patterning the light-emitting stacked layers and the first electrodes simultaneously through one dry etching process.

In some embodiments, before patterning the light-emitting stacked layers and the first electrodes simultaneously through one dry etching process, patterning the transfer epitaxial wafers further includes: forming a hard mask layer on a side of the transfer epitaxial wafer away from the second substrate, the hard mask layer covering a surface of the light-emitting stacked layer away from the first electrode.

In some embodiments, patterning the transfer epitaxial wafers includes: patterning the light-emitting stacked layers and the first electrodes respectively through two dry etching processes, so that a boundary of the light-emitting stacked layer is retracted relative to a boundary of the first electrode.

In some embodiments, among at least one two adjacent light-emitting devices, one is a first light-emitting device and another is a second light-emitting device. Sequentially forming the passivation layers and the second electrodes, includes:
forming the passivation layers, wherein a passivation layer of the first light-emitting device is a first passivation layer, and a passivation layer of the second light-emitting device is a second passivation layer; a second passivation portion of the first passivation layer is retracted relative to a boundary of the first electrode; a second passivation portion of the second passivation layer includes a first sub-portion and a second sub-portion, the first sub-portion covers a sidewall of the light-emitting stacked layer and a sidewall of the first electrode, and the first sub-portion faces the second passivation layer; the second sub-portion covers the sidewall of the light-emitting stacked layer, and is located on an edge portion of the first electrode exceeding the light-emitting stacked layer;
forming reflective layers, wherein a reflective layer is disposed on a side of the passivation layer away from the light-emitting stacked layer; a reflective layer of the first light-emitting device is a first reflective layer, and a reflective layer of the second light-emitting device is a second reflective layer; the second reflective layer covers the first sub-portion of the second passivation layer, and is connected to a portion of the first electrode of the first light-emitting device that exceeds the first passivation layer; and
forming the second electrodes, wherein a second electrode is disposed on a side of the reflective layer away from the light-emitting stacked layer and is connected to the reflective layer.

In some embodiments, among at least one two adjacent light-emitting devices, one is a third light-emitting device and another is a fourth light-emitting device. Sequentially forming the passivation layers and the second electrodes, includes:
forming the passivation layers, wherein a passivation layer of the third light-emitting device is a third passivation layer, and a passivation layer of the fourth light-emitting device is a fourth passivation layer; a second passivation portion of the third passivation layer is retracted relative to a boundary of the first electrode; a second passivation portion of the fourth passivation layer includes a first sub-portion and a second sub-portion, the first sub-portion covers a sidewall of the light-emitting stacked layer and a sidewall of the first electrode, and the first sub-portion faces the fourth passivation layer; the second sub-portion covers the sidewall of the light-emitting stacked layer, and is located on an edge portion of the first electrode exceeding the light-emitting stacked layer;
forming reflective layers, wherein a reflective layer is disposed on a side of the passivation layer away from the light-emitting stacked layer, and an orthogonal projection of the reflective layer on a driving backplane is located within an orthogonal projection of the passivation layer on the driving backplane;
forming a first planarization layer, wherein the first planarization layer is disposed on a side of the reflective layer away from the light-emitting stacked layer; and the first planarization layer is provided therein with a third via hole; and
forming the second electrodes, wherein a second electrode is disposed on the side of the reflective layer away from the light-emitting stacked layer, and a second electrode of the third light-emitting device is connected to a portion of a first electrode of the fourth light-emitting device that exceeds the passivation layer through the third via hole.

In some embodiments, after patterning the light-emitting stacked layers and the first electrodes through a dry etching process, patterning the transfer epitaxial wafers further includes: etching a sidewall of the light-emitting stacked layer and a sidewall of the first electrode through a wet etching process, so that a non-polar crystal face exposed on the sidewall of the light-emitting stacked layer is removed.

In some embodiments, forming the transfer epitaxial wafer, includes: forming an epitaxial wafer on a third substrate, the epitaxial wafer including the light-emitting stacked layer; forming a first adhesive layer on the first substrate; connecting the first substrate attached with the first adhesive layer to the epitaxial wafer; removing the third substrate; and forming the first electrode on a side of the epitaxial wafer away from the first substrate.

In some embodiments, forming the transfer epitaxial wafer, includes: forming an epitaxial wafer on the first substrate, the epitaxial wafer including the light-emitting stacked layer; and forming the first electrode on a side of the epitaxial wafer away from the first substrate.

In yet another aspect, a method for manufacturing a light-emitting substrate is provided. The method includes: forming light-emitting devices by using the method for manufacturing the light-emitting device as described in any of the above embodiments; arranging a plurality of light-emitting devices in a preset arrangement manner on a fourth substrate; removing the fourth substrate; and connecting the arranged light-emitting devices to a driving backplane.

In some embodiments, the method further includes: forming a planar electrode, wherein the planar electrode is disposed on a side of the light-emitting devices away from the driving backplane and connected to first electrodes of the light-emitting devices; forming an auxiliary cathode by using a digitization exposure process, wherein the auxiliary electrode is disposed on a side of the planar electrode away from the driving backplane and connected to the planar electrode; the auxiliary electrode is provided therein with a plurality of openings, a single opening exposes a single light-emitting device, and a shape of an orthogonal projection of the opening on the driving backplane is the same as a shape of the orthogonal projection of the light-emitting device on the driving backplane; and forming encapsulation portions, wherein an orthogonal projection of a single light-emitting device on the driving backplane is located within an orthogonal projection of a single encapsulation portion on the driving backplane.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of another display apparatus, in accordance with some embodiments;

FIG. 3 is a sectional view of a display apparatus, in accordance with some embodiments;

FIG. 4 is a top view of a light-emitting substrate, in accordance with some embodiments;

FIG. 5 is a structural diagram of a light-emitting device, in accordance with some embodiments;

FIG. 6 is a structural diagram of another light-emitting device, in accordance with some embodiments;

FIG. 7 is a structural diagram of yet another light-emitting device, in accordance with some embodiments;

FIG. 8 is a structural diagram of yet another light-emitting device, in accordance with some embodiments;

FIG. 9 is a structural diagram of yet another light-emitting device, in accordance with some embodiments;

FIG. 10 is a structural diagram of yet another light-emitting device, in accordance with some embodiments;

FIG. 11 is a structural diagram of yet another light-emitting device, in accordance with some embodiments;

FIG. 12 is a structural diagram showing the light-emitting device in FIG. 9 and the light-emitting device in FIG. 10 connected in series;

FIG. 13 is a structural diagram showing the light-emitting device in FIG. 9 and the light-emitting device in FIG. 11 connected in series;

FIG. 14 is a structural diagram of yet another light-emitting device, in accordance with some embodiments;

FIG. 15 is a diagram showing a detection result under a transmission electron microscope, in accordance with some embodiments;

FIG. 16 is a diagram showing a detection result under a scanning electron microscope, in accordance with some embodiments;

FIGS. 17 to 26 are flowcharts of a method for manufacturing a light-emitting device, in accordance with some embodiments;

FIGS. 27 and 28 are flowcharts of a method for manufacturing a light-emitting substrate, in accordance with some embodiments;

FIGS. 29 to 41 are diagrams showing steps of a method for manufacturing a light-emitting device, in accordance with some embodiments;

FIG. 42 is a diagram showing steps of a method for manufacturing a light-emitting substrate, in accordance with some embodiments;

FIG. 43 is a top view of a light-emitting substrate, in accordance with some embodiments;

FIG. 44 is a structural diagram of a light-emitting substrate including the light-emitting devices connected in series in FIG. 12, in accordance with some embodiments; and

FIG. 45 is a structural diagram of a light-emitting substrate including the light-emitting devices connected in series in FIG. 13, in accordance with some embodiments.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a plurality of” or “the plurality of” means two or more unless otherwise specified.

In the description of some embodiments, the terms such as “coupled” and “connected” and derivatives thereof may be used. The term “connected” shall be understood in a broad sense. For example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

The term such as “about”, “substantially” or “approximately” as used herein includes a stated value and an average value within an acceptable range of deviation of a particular value determined by a person of ordinary skilled in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of regions in a device, and are not intended to limit the scope of the exemplary embodiments.

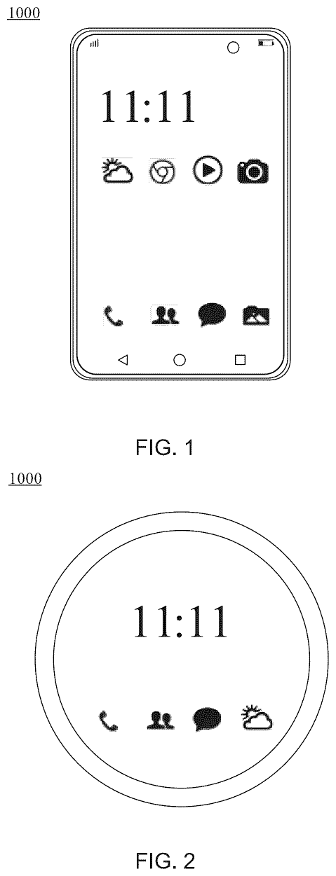

As shown in FIG. 1, some embodiments of the present disclosure provide a display apparatus 1000. The display apparatus 1000 may be any apparatus that displays an image whether in motion (e.g., a video) or stationary (e.g., a still image), and whether textual or graphical.

For example, referring to FIGS. 1 and 2, the display apparatus 1000 may be any product or component having a display function, such as a television, a notebook computer, a tablet computer, a mobile phone, a personal digital assistant (PDA), a navigator, a wearable device, a virtual reality (VR) device.

For example, as shown in FIG. 1, the display apparatus 1000 may be a portable display product. For example, the display apparatus 1000 may be a mobile phone shown in FIG. 1. As another example, referring to FIG. 2, the display apparatus 1000 may be a wearable device. For example, the display apparatus 1000 may be a watch shown in FIG. 2.

It will be noted that, depending on different application scenarios, a shape of a display surface of the display apparatus 1000 varies. The shape of the display surface of the display apparatus 1000 may be any one of a circle, an ellipse, a polygon or an irregular shape, which is not specifically limited in the embodiments of the present disclosure.

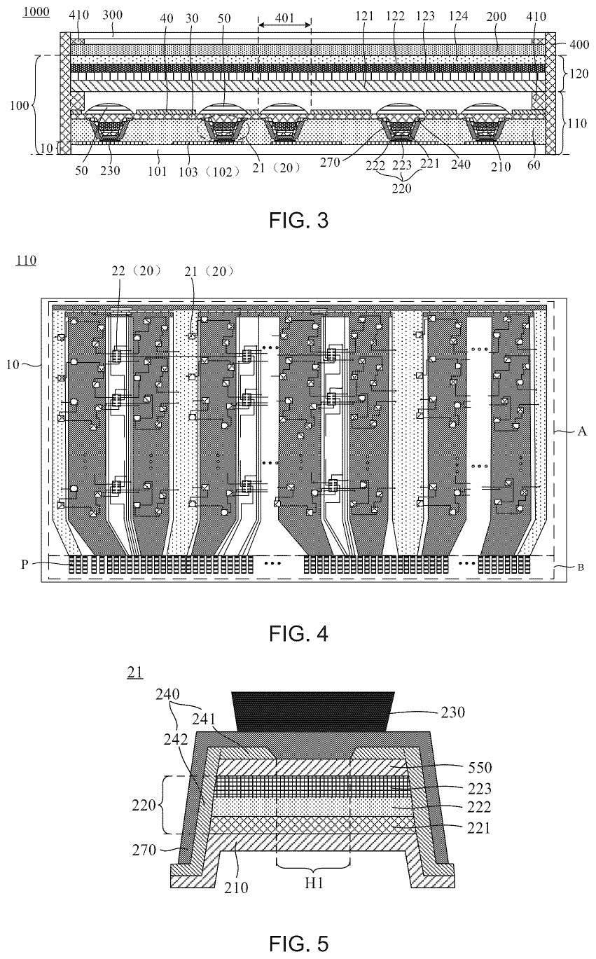

In some embodiments, referring to FIG. 3, the display apparatus 1000 may be a liquid crystal display (LCD) apparatus.

For example, referring to FIG. 3, the display apparatus 1000 includes a backlight module 100, a display panel 200 and a cover plate 300. The display panel 200 is disposed on a side of the backlight module 100 from which light is emitted. The cover plate 300 is disposed on a side of the display panel 200 away from the backlight module 100.

Referring to FIG. 3, the backlight module 100 includes a light-emitting substrate 110, and the light-emitting substrate 110 has a light-exit side and a non-light-exit side that are opposite to each other. The light-exit side refers to a side of the light-emitting substrate 110 from which light is emitted (an upper side of the light-emitting substrate 110 in FIG. 3), and the non-light-exit side refers to another side opposite to the light-exit side (a lower side of the light-emitting substrate 110 in FIG. 3). The display panel 200 is disposed on the light-exit side of the light-emitting substrate 110.

In some embodiments, referring to FIG. 3, the backlight module 100 further includes a plurality of optical films 120, and the plurality of optical films 120 are located on the light-exit side of the light-emitting substrate 110.

The light emitted from the light-emitting substrate 110 passes through the optical films 120 and then is directed to the display panel 200. That is, the display panel 200 is disposed on a side of the optical films 120 away from the light-emitting substrate 110. It will be noted that the optical films 120 modulates a wavelength of light emitted by the light-emitting substrate 110 and/or modulates a propagation direction of light.

As shown in FIG. 3, the light-emitting substrate 110 may directly emit white light. After the white light passes through the plurality of optical films 120, the propagation direction of the white light is modulated and then is directed to the display panel 200. Alternatively, the light-emitting substrate 110 may emit light of other colors (e.g., blue light), which is then directed to the display panel 200 after the plurality of optical films 120 modulates the wavelength of light and/or the propagation direction.

For example, referring to FIG. 3, the plurality of optical films 120 include a scattering layer 121, a color conversion layer 122, a diffusion sheet 123 and a composite film 124. The scattering layer 121, the color conversion layer 122, the diffusion sheet 123 and the composite film 124 may be, for example, sequentially arranged away from the display panel 200. That is, the diffusion sheet 123 may be disposed on the light-exit side of the light-emitting substrate 110; the composite film 124 is disposed on a side of the diffusion sheet 123 away from the light-emitting substrate 110; the scattering layer 121 and the color conversion layer 122 are disposed on a side of the diffusion sheet 123 close to the light-emitting substrate 110; and the display panel 200 is disposed on a side of the composite film 124 away from the light-emitting substrate 110.

The scattering layer 121 is capable of blurring the light emitted by the light-emitting substrate 110 and providing support for the color conversion layer 122, the diffusion sheet 123 and the composite film 124. Due to excitation of light of a certain color emitted by the light-emitting substrate 110, the color conversion layer 122 may convert the light into white light, so as to improve the utilization efficiency of light energy of the light-emitting substrate 110. The diffusion sheet 123 is capable of uniformizing the light passing through the diffusion sheet 123. The composite film 124 is capable of improving the light extraction efficiency of the light-emitting substrate 110, thereby increasing the display brightness of the display apparatus 1000.

It will be noted that the composite film 124 may include a brightness enhancement film (BEF) and a dual brightness enhancement film (DBEF), which increases the light flux within a certain angle range based on the principles of total reflection, refraction and polarization and in turn improves the brightness of the display apparatus 1000.

For example, as shown in FIG. 3, the light-emitting substrate 110 emits blue light. The color conversion layer 122 may include a red quantum dot material, a green quantum dot material, and a transparent material. When the blue light emitted by the light-emitting substrate 110 passes through the red quantum dot material, the blue light is converted into red light. When the blue light passes through the green quantum dot material, the blue light is converted into green light. The blue light may directly pass through the transparent material. Then, the blue light, red light and green light are mixed and superimposed in a certain proportion to present white light. Next, the scattering layer 121 and the diffusion sheet 123 modulate incident light in different propagation directions and emit the light in a uniform state, so as to ameliorate light shadow produced by the light-emitting substrate 110 and enhance the display quality of the display apparatus 1000.

In some embodiments, referring to FIG. 3, the display apparatus 1000 further includes a support frame 400, and the support frame 400 surrounds a periphery of the light-emitting substrate 110 for protection. Furthermore, two support protrusions 410 are provided on the support frame 400. One support protrusion 410 is located between the display panel 200 and the cover plate 300, and another support protrusion 410 is located between the optical film 120 and the light-emitting substrate 110, so as to provide support for the cover plate 300 and the optical film 120.

In some embodiments, referring to FIGS. 3 and 4, the light-emitting substrate 110 includes a driving backplane 10, a plurality of electronic components 20 and a planar electrode 30.

The light-emitting substrate 110 has a light-emitting region A and a peripheral region B located at least one side of the light-emitting region A. The light-emitting region A may be configured to be provided therein with the electronic components 20. For example, the electronic components 20 are arranged in the light-emitting region A. The peripheral region B may be configured to be connected to a circuit board. For example, the peripheral region B is provided therein with bonding electrodes P, and the circuit board is connected to the light-emitting substrate 110 through the bonding electrodes P.

In some examples, as shown in FIGS. 3 and 4, the electronic components E may include light-emitting devices 21 and micro chips 22.

As shown in FIGS. 3 and 4, the light-emitting devices 21 may include micro light-emitting diodes (micro LEDs) and/or mini light-emitting diodes (mini LEDs).

It will be noted that a size (e.g., a length) of the micro LED is less than 50 micrometers, for example, in a range of 10 micrometers to 50 micrometers. A size (e.g., a length) of the mini LED is in a range of 50 micrometers to 150 micrometers, for example, in a range of 80 micrometers to 120 micrometers.

As shown in FIGS. 3 and 4, the micro chips 22 may include sensor chips and/or driver chips. The sensor chip may be, for example, a photosensitive sensor chip or a thermosensitive sensor chip. A driver chip is used for providing driving signals for light-emitting devices 21.

In some examples, referring to FIG. 3, the driving backplane 10 may include a substrate 101 and a circuit layer 102, and the circuit layer 102 is disposed on the substrate 101.

It will be noted that the substrate 101 may be a rigid substrate or a flexible substrate. A material of the rigid substrate includes at least one of glass, quartz, sapphire, ceramic or polymethyl methacrylate (PMMA). A material of the flexible substrate includes at least one of epoxy resin, triazine, silicone resin or polyimide.

The circuit layer 102 includes third electrodes 103. The electronic component 20 may be fixed on the driving backplane 10 through the third electrode 103, and is electrically connected to the third electrode 103 to receive a first voltage signal. A radial dimension of the third electrode 103 may be in a range of 10 μm to 100 μm. For example, the radial dimension of the third electrode 103 is any one of 10 μm, 20 μm, 30 μm, 40 μm, 50 μm, 60 μm, 70 μm, 80 μm, 90 μm, and 100 μm.

In some examples, referring to FIGS. 3 and 4, the planar electrode 30 is disposed on a side of the electronic components 20 (light-emitting devices 21) away from the driving backplane 10, and is connected to the electronic components 20 (light-emitting devices 21) to receive a second voltage signal. The first voltage signal and the second voltage signal are different, so as to provide a power supply voltage to the electronic component 20.

Here, the planar electrode 30 may, for example, cover the light-emitting region A and extend to the peripheral region B. In this way, all electronic components 20 may be connected to the planar electrode 30, and the planar electrode 30 may be easily connected to the driving backplane 10 to receive the second voltage signal provided by the driving backplane 10, resulting in simple process and low costs.

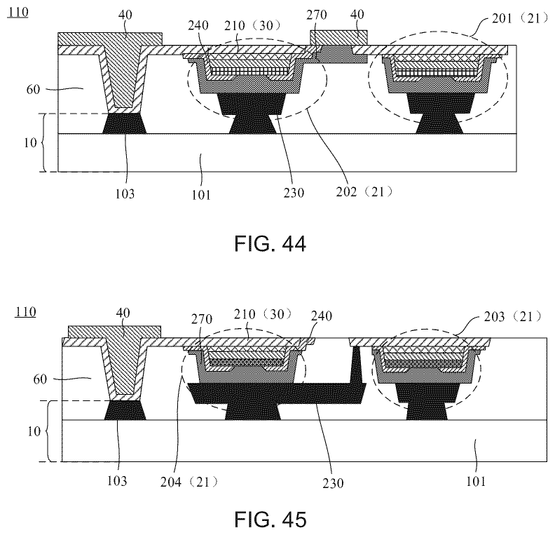

It will be noted that, referring to FIGS. 44 and 45, for at least two light-emitting devices 21 connected in series, the planar electrode 30 may include a plurality of sub-electrodes insulated from each other, the at least two light-emitting devices 21 connected in series are respectively connected to different sub-electrodes, and the plurality of sub-electrodes corresponding to the at least two light-emitting devices 21 connected in series are arranged separately from each other.

In some embodiments, as shown in FIGS. 3, 43 and 44, the light-emitting substrate 110 further includes a plurality of encapsulation portions 50 arranged at intervals, and the plurality of encapsulation portions 50 are disposed on a side of the planar electrode 30 away from the driving backplane 10. An orthogonal projection of an electronic component 20 (e.g., a light-emitting device 21) on the driving backplane 10 is located within an orthogonal projection of an encapsulation portion 50 on the driving backplane 10. That is, a single encapsulation portion 50 encapsulates a single electronic component 20 to protect the electronic component 20, thus improving the water resistance, corrosion resistance and light extraction efficiency of the light-emitting substrate 110.

It will be noted that the encapsulation portion 50 may be formed through spraying high thixotropic glue on the electronic component 20 by a dispenser and then a curing process. In addition, the encapsulation portion 50 may be in a shape of a spherical cap or a semi-ellipsoidal sphere, which is not specifically limited in the embodiments of the present disclosure.

A material of the encapsulation portion 50 includes resin and/or inorganic material, and the inorganic material includes at least one of niobium pentoxide, titanium oxide or silicon oxide. It will be understood that the material of the encapsulation portion 50 may be adaptively adjusted for different types of electronic components 20. For example, the electronic components 20 are optical components (such as the light-emitting devices 21), and the encapsulation portions 50 are made of a transparent material. The transparent material may include transparent silicone or transparent resin. The electronic components 20 are non-optical components (such as the driver chips), and the material of the encapsulation portion 50 has no requirements on light transmittance, which may be a transparent material, a reflective material, or a light-absorbing material. The reflective material may include at least one of white ink, white resin or silicon-based white glue. The light-absorbing material may include at least one of black ink, black resin or silicon-based black glue.

In some embodiments, as shown in FIGS. 3, 43 and 44, the light-emitting substrate 110 further includes an auxiliary electrode 40. The auxiliary electrode 40 is disposed on the side of the planar electrode 30 away from the driving backplane 10, and is connected to the planar electrode 30, so as to reduce the resistance of transmitting the second voltage signal, reduce the voltage drop, and reduce the difference in the second voltage signal of the light-emitting devices 21 at different positions, and in turn to improve the brightness uniformity of the light-emitting substrate 110.

The auxiliary electrode 40 may be provided therein with a plurality of openings 401. An opening 401 exposes a light-emitting device 21. A shape of an orthogonal projection of the opening 401 on the driving backplane 10 is the same as a shape of an orthogonal projection of the light-emitting device 21 on the driving backplane 10. In this way, the auxiliary electrode 40 may block light between the light-emitting devices 21 without adding a light-shielding layer, which is conducive to reducing a thickness of the display apparatus 1000.

For example, referring to FIGS. 4, 43 and 44, the auxiliary electrode 40 may cover regions between the plurality of encapsulation portions 50. That is, a boundary of the orthogonal projection of the opening 401 of the auxiliary cathode 40 on the driving backplane 10 is located between boundaries of orthogonal projections of the light-emitting device 21 and the encapsulation portion 50 on the driving backplane 10. Of course, as shown in FIG. 3, the opening 401 of the auxiliary electrode 40 may also expose the encapsulation portion 50. For example, a distance between a boundary of the opening 401 of the auxiliary electrode 40 and a boundary of the encapsulation portion 50 is less than or equal to a process limit value, and the light between the light-emitting devices 21 may still be effectively blocked.

It will be noted that the auxiliary electrode 40 may be made of a light-shielding conductive material. For example, the material of the auxiliary electrode 40 material includes a light-shielding metal, such as at least one of titanium, aluminum, chromium, platinum, or gold. In addition, the auxiliary electrode 40 may be formed by a digitization exposure process to achieve high-precision morphology control.

However, in the related art, the process of manufacturing the light-emitting device is complicated, the manufacturing efficiency and yield are low, and the manufacturing costs are high.

As shown in FIGS. 5 to 8, some embodiments of the present disclosure provide a light-emitting device 21, including a first electrode 210, a light-emitting stacked layer 220, a second electrode 230 and a passivation layer 240.

As shown in FIG. 5, the first electrode 210 of the light-emitting device 21 is connected to the planar electrode 30 (see FIG. 3). The first electrode 210 is a light-exit side of the light-emitting device 21, and the transmittance of the first electrode 210 is greater than or equal to 99%. For example, a material of the first electrode 210 includes a transparent metal material. For example, the material of the first electrode 210 includes indium tin oxide and/or indium zinc oxide.

It will be noted that a thickness of the first electrode 210 is in a range of 0.1 μm to 0.6 μm. In some examples, as shown in FIG. 5, the thickness of the first electrode 210 is in a range of 0.1 μm to 0.3 μm. In some other examples, as shown in FIG. 7, the thickness of the first electrode 210 is in a range of 0.2 μm to 0.6 μm. For example, the thickness of the first electrode 210 is any one of 0.1 μm, 0.15 μm, 0.2 μm, 0.25 μm, 0.3 μm, 0.35 μm, 0.4 μm, 0.45 μm, 0.5 μm, 0.55 μm, and 0.6 μm.

As shown in FIG. 5, the light-emitting stacked layer 220 is disposed on a side (an upper side in FIG. 5) of the first electrode 210 and is connected to the first electrode 210. That is, the light-emitting stacked layer 220 is disposed on a side of the first electrode 210 away from the planar electrode 30 (see FIG. 3). The light-emitting stacked layer 220 includes a quantum well layer 222, and a first semiconductor doped layer 221 and a second semiconductor doped layer 223 that are respectively disposed on two opposite sides of the quantum well layer 222.

Here, a thickness of the first semiconductor doped layer 221 may be in a range of 0.5 μm to 2 μm, and a thickness of the second semiconductor doped layer 223 may be in a range of 0.5 μm to 2 μm. For example, the thickness of the first semiconductor doped layer 221 may be any one of 0.5 μm, 0.8 μm, 1 μm, 1.1 μm, 1.3 μm, 1.5 μm, 1.8 μm, and 2 μm. For example, the thickness of the second semiconductor doped layer 223 may be any one of 0.5 μm, 0.8 μm, 1 μm, 1.1 μm, 1.3 μm, 1.5 μm, 1.8 μm, and 2 μm.

It will be noted that, among the first semiconductor doped layer 221 and the second semiconductor doped layer 223, one is an N-type doped semiconductor layer, and the other is a P-type doped semiconductor layer. For example, the first semiconductor doped layer 221 is an N-type doped semiconductor layer, and the second semiconductor doped layer 223 is made of P-type doped gallium nitride. The material of the quantum well layer 222 includes gallium nitride and/or indium gallium nitride.

As shown in FIG. 5, the second electrode 230 is disposed on a side of the light-emitting stacked layer 220 away from the first electrode 210. The second electrode 230 is configured to be connected to the driving backplane 10 (see FIG. 3). That is, the second electrode 230 of the light-emitting device 21 is connected to the third electrode 103 (see FIG. 3) of the driving backplane 10 (see FIG. 3). A material of the second electrode 230 includes a metal material. For example, the material of the second electrode 230 includes at least one of nickel, gold, copper, and tin. For example, the second electrode 230 includes a nickel layer, a gold layer, and a tin layer that are stacked; a thicknesses of the nickel layer is in a range of 0.5 μm to 2 μm; a thicknesses of the gold layer is in a range of 1 μm to 2 μm; and a thicknesses of the tin layer is in a range of 0.2 μm to 1 μm.

It will be noted that a radial dimension of the second electrode 230 is less than the radial dimension of the third electrode 103, so as to facilitate the alignment and connection between the light-emitting device 21 and the third electrode 103. For example, the radial dimension of the second electrode 230 is in a range of 5 μm to 20 μm. For example, the radial dimension of the second electrode 230 is any one of 5 μm, 8 μm, 10 μm, 11 μm, 13 μm, 15 μm, 18 μm, and 20 μm.

As shown in FIG. 5, the passivation layer 240 includes a first passivation portion 241 and a second passivation portion 242. The first passivation portion 241 covers a surface of the light-emitting stacked layer 220 away from the first electrode 210. The first passivation portion 241 is provided therein with a first via hole H1. The second electrode 230 is connected to the light-emitting stacked layer 220 through the first via hole H1. The second passivation portion 242 covers a sidewall of the light-emitting stacked layer 220 and extends to a side of the light-emitting stacked layer 220 away from the second electrode 230. A distance between a portion of the second passivation portion 242 exceeding the light-emitting stacked layer 220 and the light-emitting stacked layer 220 is greater than the thickness of the first electrode 210.

A material of the passivation layer 240 includes an inorganic material. For example, the material of the passivation layer 240 includes at least one of silicon oxide, silicon nitride, or aluminum oxide. For example, the passivation layer 240 may include a silicon oxide layer and a silicon nitride layer that are stacked.

It will be noted that, a thickness of the passivation layer 240 is in a range of 0.2 μm to 0.5 μm. For example, the thickness of the passivation layer 240 is any one of 0.2 μm, 0.25 μm, 0.3 μm, 0.35 μm, 0.4 μm, 0.45 μm, and 0.5 μm.

In this case, during the process of manufacturing the plurality of light-emitting devices 21, light-emitting stacked layers 220 and first electrodes 210 of the plurality of light-emitting devices 21 may be transferred onto the same substrate (a second substrate 520 as mentioned below) through an adhesive layer (a second adhesive layer 570 as mentioned below); then, passivation layers 240 and second electrodes 230 are formed. Thus, the manufacturing efficiency and manufacturing yield are improved, and the manufacturing costs are reduced. As for the detailed process, reference may be made to the following description.

In some embodiments, as shown in FIG. 5, the second passivation portion 242 covers the sidewall of the light-emitting stacked layer 220 and extends to the side of the light-emitting stacked layer 220 away from the second electrode 230. The second passivation portion 242 is located on a side of the first electrode 210 close to the second electrode 230.

It will be noted that the first electrode 210 may be of an independent structure, or may be a portion of the above-mentioned planar electrode 30 connecting the light-emitting stacked layer 220, which is not specifically limited in the embodiments of the present disclosure.

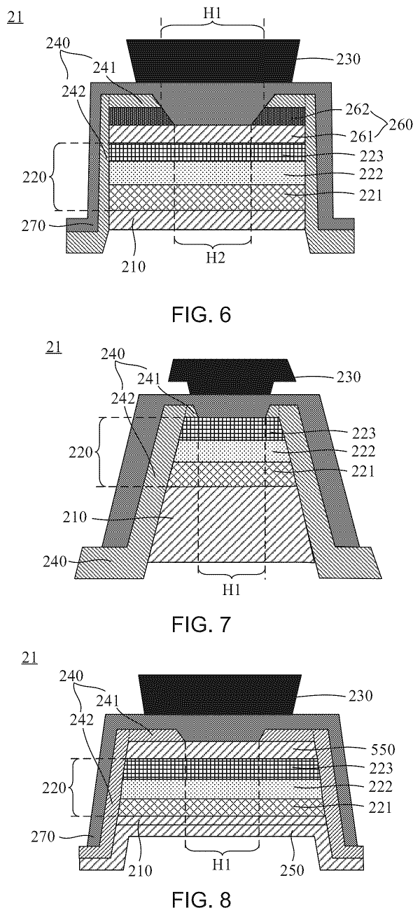

In some other embodiments, as shown in FIGS. 6 and 7, the second passivation portion 242 covers the sidewall of the light-emitting stacked layer 220 and the sidewall of the first electrode 210, and extends to a side of the first electrode 210 away from the second electrode 230. In this case, the light-emitting stacked layer 220 and the first electrode 210 may be patterned through one etching process, and the process is simple.

In some embodiments, referring to FIG. 8, the light-emitting device 21 further includes a connection electrode 250, and the connection electrode 250 is disposed on the side of the first electrode 210 away from the second electrode 230. The connection electrode 250 covers the first electrode 210 and extends to a surface of the second passivation portion 242 away from the first passivation portion 241. Here, a boundary of the connection electrode 250 may be flush with a boundary of the passivation layer 240, for example.

It will be noted that the transmittance of the connection electrode 250 is greater than or equal to 99%. For example, a material of the connection electrode 250 includes a transparent metal material. For example, the material of the connection electrode 250 includes indium tin oxide and/or indium zinc oxide. In addition, the connection electrode 250 may be of an independent structure, or may be a portion of the above-mentioned planar electrode 30 connecting the first electrode 210, which is not specifically limited in the embodiments of the present disclosure.

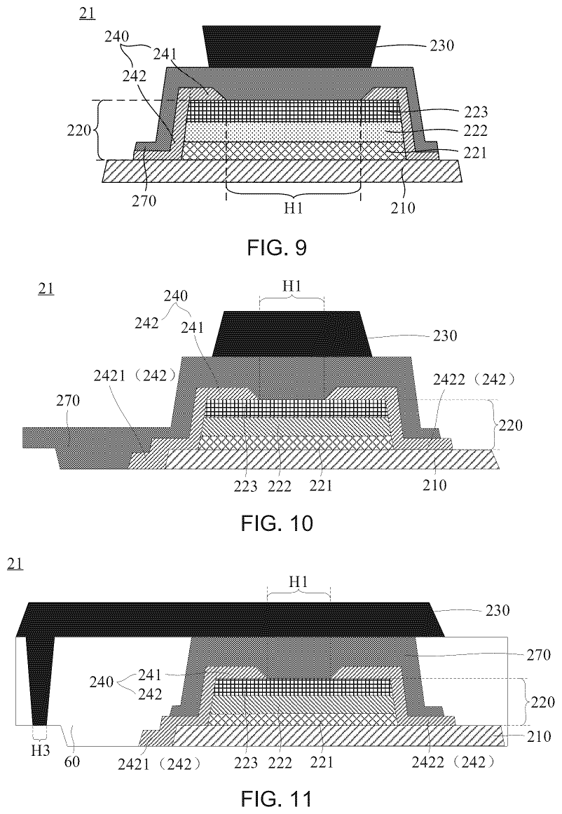

As shown in FIGS. 9 to 11, some other embodiments of the present disclosure provide a light-emitting device 21, including a first electrode 210, a light-emitting stacked layer 220, a second electrode 230 and a passivation layer 240.

As shown in FIG. 9, the first electrode 210 of the light-emitting device 21 is connected to the planar electrode 30 (see FIG. 3). The first electrode 210 is a light-exit side of the light-emitting device 21, and the transmittance of the first electrode 210 is greater than or equal to 99%. For example, a material of the first electrode 210 includes a transparent metal material. For example, the material of the first electrode 210 includes indium tin oxide and/or indium zinc oxide.

It will be noted that a thickness of the first electrode 210 is in a range of 0.1 μm to 0.6 μm. For example, the thickness of the first electrode 210 is any one of 0.1 μm, 0.15 μm, 0.2 μm, 0.25 μm, 0.3 μm, 0.35 μm, 0.4 μm, 0.45 μm, 0.5 μm, 0.55 μm, and 0.6 μm.

As shown in FIG. 9, the light-emitting stacked layer 220 is disposed on a side (an upper side in FIG. 9) of the first electrode 210 and is connected to the first electrode 210. That is, the light-emitting stacked layer 220 is disposed on a side of the first electrode 210 away from the planar electrode 30 (see FIG. 3). A boundary of the light-emitting stacked layer 220 is retracted relative to a boundary of the first electrode 210. The light-emitting stacked layer 220 includes a quantum well layer 222, and a first semiconductor doped layer 221 and a second semiconductor doped layer 223 that are respectively disposed on two opposite sides of the quantum well layer 222.

It will be noted that, among the first semiconductor doped layer 221 and the second semiconductor doped layer 223, one is an N-type doped semiconductor layer, and the other is a P-type doped semiconductor layer. For example, the first semiconductor doped layer 221 is an N-type doped semiconductor layer, and the second semiconductor doped layer 223 is made of P-type doped gallium nitride. The material of the quantum well layer 222 includes gallium nitride and/or indium gallium nitride.

As shown in FIG. 9, the second electrode 230 is disposed on a side of the light-emitting stacked layer 220 away from the first electrode 210. The second electrode 230 is configured to be connected to the driving backplane 10 (see FIG. 3). That is, the second electrode 230 of the light-emitting device 21 is connected to the third electrode 103 (see FIG. 3) of the driving backplane 10 (see FIG. 3). A material of the second electrode 230 includes a metal material. For example, the material of the second electrode 230 includes at least one of nickel, gold, copper, and tin. For example, the second electrode 230 includes a nickel layer, a gold layer, and a tin layer that are stacked; a thicknesses of the nickel layer is in a range of 0.5 μm to 2 μm; a thicknesses of the gold layer is in a range of 1 μm to 2 μm; and a thicknesses of the tin layer is in a range of 0.2 μm to 1 μm.

It will be noted that a radial dimension of the second electrode 230 is less than the radial dimension of the third electrode 103, so as to facilitate the alignment and connection between the light-emitting device 21 and the third electrode 103. For example, the radial dimension of the second electrode 230 is in a range of 5 μm to 20 μm. For example, the radial dimension of the second electrode 230 is any one of 5 μm, 8 μm, 10 μm, 11 μm, 13 μm, 15 μm, 18 μm, and 20 μm.

As shown in FIG. 9, the passivation layer 240 includes a first passivation portion 241 and a second passivation portion 242. The first passivation portion 241 covers a surface of the light-emitting stacked layer 220 away from the first electrode 210. The first passivation portion 241 is provided therein with a first via hole H1. The second electrode 230 is connected to the light-emitting stacked layer 220 through the first via hole H1. The second passivation portion 242 covers the sidewall of the light-emitting stacked layer 220, and at least part of an edge of the first electrode 210 exceeds the second passivation portion 242.

A material of the passivation layer 240 includes an inorganic material. For example, the material of the passivation layer 240 includes at least one of silicon oxide, silicon nitride, or aluminum oxide. For example, the passivation layer 240 may include a silicon oxide layer and a silicon nitride layer that are stacked.

It will be noted that, a thickness of the passivation layer 240 is in a range of 0.2 μm to 0.5 μm. For example, the thickness of the passivation layer 240 is any one of 0.2 μm, 0.25 μm, 0.3 μm, 0.35 μm, 0.4 μm, 0.45 μm, and 0.5 μm.

In this case, during the process of manufacturing the plurality of light-emitting devices 21, light-emitting stacked layers 220 and first electrodes 210 of the plurality of light-emitting devices 21 may be transferred onto the same substrate (a second substrate 520 as mentioned below) through an adhesive layer (a second adhesive layer 570 as mentioned below), and the light-emitting stacked layers 220 and the first electrodes 210 may be etched separately; then, passivation layers 240 and second electrodes 230 are formed. Thus, the manufacturing efficiency and manufacturing yield are improved, and the manufacturing costs are reduced. As for the detailed process, reference may be made to the following description.

In addition, during the process of manufacturing two light-emitting devices 21 connected in series, the second electrode 230 of one light-emitting device 21 may be connected to a portion of the first electrode 210 of another light-emitting device 21 that exceeds the passivation layer 240, so as to simplify the manufacturing process of the light-emitting devices 21 connected in series and reduce the manufacturing costs.

In some examples, as shown in FIG. 9, a circumferential boundary of the first electrode 210 exceeds the passivation layer 240. That is, the second passivation portion 242 is located on an edge portion of the first electrode 210 that exceeds the light-emitting stacked layer 220, and an outer boundary of the second passivation portion 242 is retracted relative to the boundary of the first electrode 210. In this way, during the process of manufacturing the light-emitting device 21, the passivation layer 240 are not in contact with the substrate (the second substrate 520 as mentioned below), which facilitates the light-emitting device 21 being separated from the substrate (the second substrate 520 as mentioned below).

In some other examples, as shown in FIGS. 10 and 11, a part of the circumferential boundary of the first electrode 210 exceeds the passivation layer 240.

For example, the second passivation portion 242 includes a first sub-portion 2421 and a second sub-portion 2422 that are connected along a circumferential direction of the light-emitting stacked layer 220; an edge portion of the first electrode 210 corresponding to the first sub-portion 2421 does not exceed the passivation layer 240; and an edge portion of the first electrode 210 corresponding to the second sub-portion 2422 exceeds the passivation layer 240, that is, exceeds the second passivation portion 242.

The first sub-portion 2421 covers a part of the sidewall of the light-emitting stacked layer 220 and a part of the sidewall of the first electrode 210, and an end of the first sub-portion 2421 away from the second electrode 230 may be flush with a surface of the first electrode 210 away from the second electrode 230. The second sub-portion 2422 covers another part of the sidewall of the light-emitting stacked layer 220, and is located on an edge portion of the first electrode 210 that exceeds the light-emitting stacked layer 210.

In this case, among two light-emitting devices 21 connected in series, the second electrode 230 of one light-emitting device 21 may be connected to a portion of the first electrode 210 of another light-emitting device 21 that exceeds the passivation layer 240 in different ways.

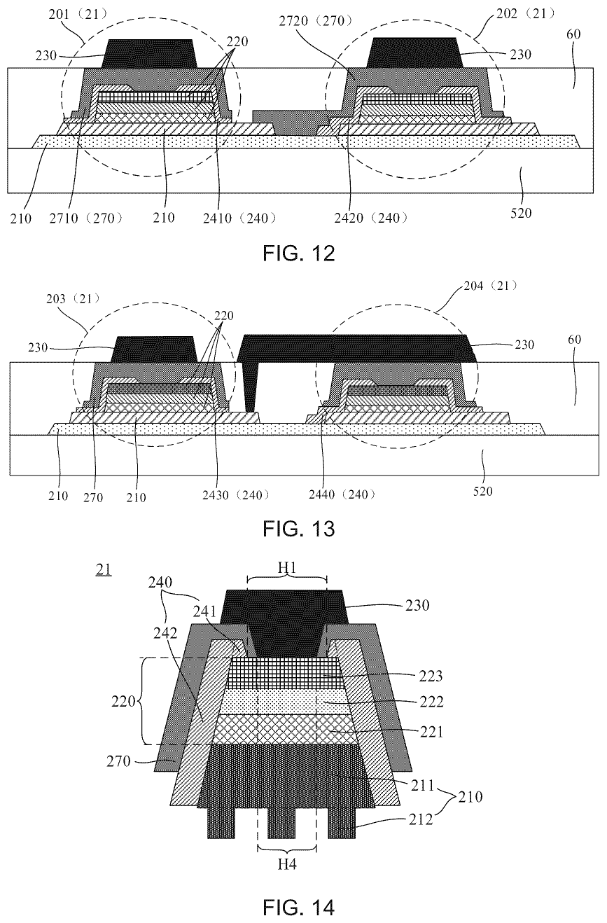

In some embodiments, as shown in FIG. 12, among at least two adjacent light-emitting devices 21, one is a first light-emitting device 201, and another is a second light-emitting device 202. The passivation layer 240 of the first light-emitting device 201 is a first passivation layer 2410, and the passivation layer 240 of the second light-emitting device 202 is a second passivation layer 2420.

Referring to FIGS. 9, 10 and 12, the second passivation portion 242 of the first passivation layer 2410 is retracted relative to the boundary of the first electrode 210. The second passivation portion 242 of the second passivation layer 2420 includes a first sub-portion 2421 and a second sub-portion 2422; the first sub-portion 2421 covers a part of the sidewall of the light-emitting stacked layer 220 and a part of the sidewall of the first electrode 210; and the second sub-portion 2422 covers another part of the sidewall of the light-emitting stacked layer 220 and is located on an edge portion of the first electrode 210 that exceeds the light-emitting stacked layer 220.

On this basis, each of the first light-emitting device 201 and the second light-emitting device 202 includes a reflective layer 270, and the reflective layer 270 is disposed on a side of the passivation layer 240 away from the light-emitting stacked layer 220. The first sub-portion 2421 of the second light-emitting device 202 faces the first light-emitting device 201. The reflective layer 270 of the second light-emitting device 202 covers the first sub-portion 2421 and is connected to a portion of the first electrode 210 of the first light-emitting device 201 that exceeds the passivation layer 240.

In addition, the light-emitting substrate 110 further includes a first planarization layer 60, and the first planarization layer 60 is disposed on a side of the second electrode 230 close to the light-emitting stacked layer 220. For example, the first planarization layer 60 is disposed between the second electrode 230 and the reflective layer 270.

In this case, as shown in FIG. 44, the light-emitting devices 21 connected in series may be connected to the driving backplane 10, so as to simplify the process and reduce the manufacturing costs.

In some other embodiments, as shown in FIG. 13, among at least two adjacent light-emitting devices 21, one is a third light-emitting device 203, and another is a fourth light-emitting device 204. The passivation layer 240 of the third light-emitting device 203 is a third passivation layer 2430, and the passivation layer 240 of the fourth light-emitting device 204 is a fourth passivation layer 2440.

Referring to FIGS. 9, 11 and 13, the second passivation portion 242 of the third passivation layer 2430 is retracted relative to the boundary of the first electrode 210. The second passivation portion 242 of the fourth passivation layer 2440 includes a first sub-portion 2421 and a second sub-portion 2422, and the first sub-portion 2421 covers a part of the sidewall of the light-emitting stacked layer 220 and a part of the sidewall of the first electrode 210. The second sub-portion 2422 covers another part of the sidewall of the light-emitting stacked layer 220, and is located on an edge portion of the first electrode 210 that exceeds the light-emitting stacked layer 220.

On this basis, the light-emitting substrate 110 further includes a first planarization layer 60, and the first planarization layer 60 is disposed on the side of the second electrode 230 close to the light-emitting stacked layer 220. For example, the first planarization layer 60 is disposed between the second electrode 230 and the reflective layer 270.

The first planarization layer 60 is provided therein with a third via hole H3, and the second electrode 230 of the third light-emitting device 203 is connected to a portion of the first electrode 210 of the fourth light-emitting device 204 that exceeds the passivation layer 240 through the third via hole H3.

In this case, as shown in FIG. 45, the light-emitting devices 21 connected in series may be connected to the driving backplane 10, so as to simplify the process and reduce the manufacturing costs.

As shown in FIG. 14, yet some other embodiments of the present disclosure provide a light-emitting device 21, including a first electrode 210, a light-emitting stacked layer 220, a second electrode 230 and a passivation layer 240.

As shown in FIG. 14, the first electrode 210 of the light-emitting device 21 is connected to the planar electrode 30 (see FIG. 3), and the first electrode 210 includes an electrode body 211 and a plurality of bonding protrusions 212. The plurality of bonding protrusions 212 are arranged at intervals on a side of the electrode body 211 (close to the planar electrode 30 (see FIG. 3)). The first electrode 210 is a light-exit side of the light-emitting device 21, and the transmittance of the first electrode 210 is greater than or equal to 99%. For example, a material of the first electrode 210 includes a transparent metal material. For example, the material of the first electrode 210 includes indium tin oxide and/or indium zinc oxide.

It will be noted that a thickness of the first electrode 210 is in a range of 0.1 μm to 0.6 μm. For example, a thickness of the electrode body 211 is in a range of 0.1 μm to 0.3 μm, and a thickness of the bonding protrusion 212 is in a range of 0.1 μm to 0.3 μm. For example, the thickness of the electrode body 211 and/or the thickness of the bonding protrusion 212 is any one of 0.1 μm, 0.15 μm, 0.2 μm, 0.25 μm, and 0.3 μm.

In addition, the arrangement of the plurality of bonding protrusions 212 varies. For example, the plurality of bonding protrusions 212 may be arranged in an array. The plurality of bonding protrusions 212 may be arranged at substantially equal intervals. In this way, during the process of manufacturing the light-emitting devices 21, the first electrodes 210 of the plurality of light-emitting devices 21 may be transferred onto the same substrate by bonding, and the bonding strength of the first electrodes 210 of the plurality of light-emitting devices 21 is substantially the same, which is beneficial for the detachment of the light-emitting devices 21.

It will be noted that a ratio of an area of an orthogonal projection of the bonding protrusion 212 on the driving backplane 10 to a light-emitting area of the light-emitting device 21 is in a range of 0.1 to 0.8, the bonding strength meets the requirements, and the detachment is easy. For example, a radial dimension of the bonding protrusion 212 is in a range of 0.1 μm to 0.8 μm. For example, the radial dimension of the bonding protrusion 212 is any one of 0.1 μm, 0.2 μm, 0.3 μm, 0.4 μm, 0.5 μm, 0.6 μm, 0.7 μm, and 0.8 μm.

As shown in FIG. 14, the light-emitting stacked layer 220 is disposed on a side of the first electrode 210 away from the bonding protrusions 212, and is connected to the electrode body 211. That is, the light-emitting stacked layer is disposed on a side of the first electrode layer away from the planar electrode 30. The light-emitting stacked layer 220 includes a quantum well layer 222, and a first semiconductor doped layer 221 and a second semiconductor doped layer 223 that are respectively disposed on two opposite sides of the quantum well layer 222.

It will be noted that, among the first semiconductor doped layer 221 and the second semiconductor doped layer 223, one is an N-type doped semiconductor layer, and the other is a P-type doped semiconductor layer. For example, the first semiconductor doped layer 221 is an N-type doped semiconductor layer, and the second semiconductor doped layer 223 is made of P-type doped gallium nitride. The material of the quantum well layer 222 includes gallium nitride and/or indium gallium nitride.

As shown in FIG. 14, the second electrode 230 is disposed on a side of the light-emitting stacked layer 220 away from the first electrode 210. The second electrode 230 is configured to be connected to the driving backplane 10 (see FIG. 3). That is, the second electrode 230 of the light-emitting device 21 is connected to the third electrode 103 (see FIG. 3) of the driving backplane 10 (see FIG. 3). A material of the second electrode 230 includes a metal material. For example, the material of the second electrode 230 includes at least one of nickel, gold, copper, and tin. For example, the second electrode 230 includes a nickel layer, a gold layer, and a tin layer that are stacked; a thicknesses of the nickel layer is in a range of 0.5 μm to 2 μm; a thicknesses of the gold layer is in a range of 1 μm to 2 μm; and a thicknesses of the tin layer is in a range of 0.2 μm to 1 μm.

It will be noted that a radial dimension of the second electrode 230 is less than the radial dimension of the third electrode 103, so as to facilitate the alignment and connection between the light-emitting device 21 and the third electrode 103. For example, the radial dimension of the second electrode 230 is in a range of 5 μm to 20 μm. For example, the radial dimension of the second electrode 230 is any one of 5 μm, 8 μm, 10 μm, 11 μm, 13 μm, 15 μm, 18 μm, and 20 μm.

As shown in FIG. 14, the passivation layer 240 includes a first passivation portion 241 and a second passivation portion 242. The first passivation portion 241 covers a surface of the light-emitting stacked layer 220 away from the first electrode 210. The first passivation portion 241 is provided therein with a first via hole H1. The second electrode 230 is connected to the light-emitting stacked layer 220 through the first via hole H1. The second passivation portion 242 covers at least part of sidewalls of the light-emitting stacked layer 220 and the electrode body 211.

For example, the second passivation portion 242 covers the sidewall of the light-emitting stacked layer 220 and the sidewall of the electrode body 211, and an end of the second passivation portion 242 away from the first passivation portion 241 is substantially flush with a surface of the electrode body 211 away from the first passivation portion 241.

As another example, as shown in FIG. 14, the second passivation portion 242 covers the sidewall of the light-emitting stacked layer 220 and a part of the sidewall of the electrode body 211; and an end of the second passivation portion 242 away from the first passivation portion 241 is located between a surface of the electrode body 211 away from the first passivation portion 241 and a surface of the electrode body 211 close to the first passivation portion 241.

A material of the passivation layer 240 includes an inorganic material. For example, the material of the passivation layer 240 includes at least one of silicon oxide, silicon nitride, or aluminum oxide. For example, the passivation layer 240 may include a silicon oxide layer and a silicon nitride layer that are stacked.

It will be noted that, a thickness of the passivation layer 240 is in a range of 0.2 μm to 0.5 μm. For example, the thickness of the passivation layer 240 is any one of 0.2 μm, 0.25 μm, 0.3 μm, 0.35 μm, 0.4 μm, 0.45 μm, and 0.5 μm.

In this case, during the process of manufacturing the plurality of light-emitting devices 21, light-emitting stacked layers 220 and first electrodes 210 of the plurality of light-emitting devices 21 may be transferred onto the same substrate (a second substrate 520 as mentioned below) by bonding; then, passivation layers 240 and second electrodes 230 are formed. Thus, the manufacturing efficiency and manufacturing yield are improved, and the manufacturing costs are reduced. As for the detailed process, reference may be made to the following description.

Some embodiments of the present disclosure will be schematically described below by taking the light-emitting device 21 in which the second passivation portion 242 covers the sidewall of the light-emitting stacked layer 220 and the sidewall of the electrode body 211 and extends to the side of the first electrode 210 away from the second electrode 230 as an example. However, the implementations of the present disclosure are not limited thereto, and any other light-emitting device 21 mentioned above may also be considered as long as the same technical concept is applied.

In some embodiments, referring to FIG. 7, boundaries of two surfaces, facing away from each other, of the light-emitting stacked layer 220 and the first electrode 210 are connected to form a slope surface, and a slope angle of the slope surface is greater than or equal to 60°. In this case, a slope angle of a side surface of the light-emitting stacked layer 220 is relatively large, so that the second electrode 230 and the light-emitting stacked layer 220 have a relatively large contact area, which increases the light-emitting area. Moreover, the contact area between the passivation layer 240 and an upper surface of the light-emitting stacked layer 220 is larger, providing better coverage and adhesion.

In some embodiments, referring to FIG. 6, the light-emitting device 21 further includes a hard mask layer 260, and the hard mask layer 260 is disposed between a surface of the light-emitting stacked layer 220 away from the first electrode 210 and the passivation layer 240. The hard mask layer 260 is provided therein with a second via hole H2, and the second electrode 230 is connected to the light-emitting stacked layer 220 through the first via hole H1 and the second via hole H2.

In this case, a slope angle of the sidewall of the light-emitting stacked layer 220 may be larger. For example, the boundaries of two surfaces, facing away from each other, of the light-emitting stacked layer 220 and the first electrode 210 are connected to form the slope surface, and the slope angle of the slope surface is greater than or equal to 80°, so as to further increase the slope angle of the side surface of the light-emitting stacked layer 220, increase the contact area between the second electrode 230 and the light-emitting stacked layer 220, and in turn further increase the light-emitting area. Moreover, the contact area between the passivation layer 240 and an upper surface of the light-emitting stacked layer 220 is larger, providing better coverage and adhesion.

It will be noted that the hard mask layer 260 may be of a single-layer structure. Alternatively, the hard mask layer 260 may be of a multi-layer structure. For example, referring to FIGS. 6 and 39, during the etching process, the hard mask layer 260 may include an indium tin oxide layer 261, a silicon oxide layer 262, and a photoresist layer 263 (not shown in FIG. 6) that are stacked in sequence, and the indium tin oxide layer 261 is close to the light-emitting stacked layer 220. After the etching is completed, the photoresist layer 263 is removed and a hole is formed in the silicon oxide layer 262.

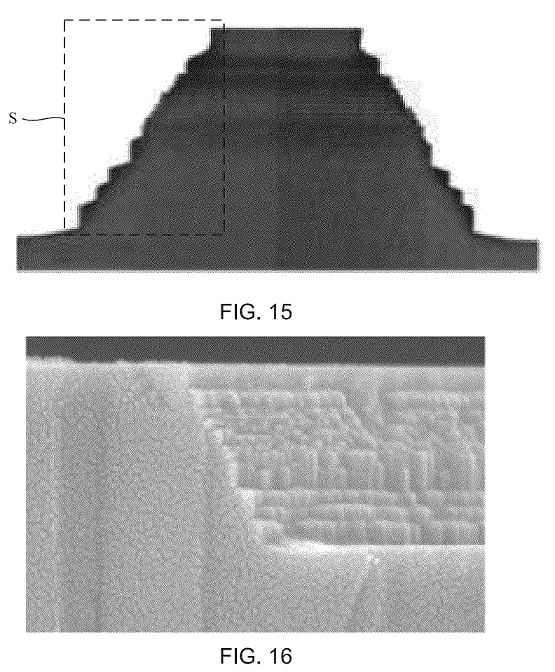

FIG. 15 is a diagram showing a detection result under a transmission electron microscope according to some embodiments. FIG. 16 is a diagram showing a detection result under a scanning electron microscope according to some embodiments.

In some embodiments, referring to FIGS. 15 and 16, the sidewall of the light-emitting stacked layer 220 is of a stepped structure S; and the circumferential boundary of the light-emitting stacked layer 220 is indented in a stepped manner along a direction from the second electrode 230 to the first electrode 210. The stepped structure S may be formed by etching the sidewall of the light-emitting stacked layer 220 and the sidewall of the first electrode 210 through a wet etching process, so that a non-polar crystal face exposed on the sidewall of the light-emitting stacked layer 220 is removed, which improves the light-emitting efficiency of the light-emitting device 21.

For example, the light-emitting stacked layer 220 includes a quantum well layer 222, and a first semiconductor doped layer 221 and a second semiconductor doped layer 223 that are respectively disposed on two opposite sides of the quantum well layer 222. On this basis, the first semiconductor doped layer 221, the quantum well layer 222 and the second semiconductor doped layer 223 each form a single step.

It will be noted that, the dopant concentrations at different positions in the first semiconductor doped layer 221 and the second semiconductor doped layer 223 may be different; therefore, each step may also include a plurality of sub-steps, which will not be specifically limited in the embodiments of the present disclosure.

In some embodiments, referring to FIGS. 5 to 14, the light-emitting device 21 further includes a reflective layer 270, and the reflective layer 270 is disposed on a side of the passivation layer 240 away from the light-emitting stacked layer 220.

In some examples, as shown in FIG. 14, the reflective layer 270 is provided therein with a fourth via hole H4, and the second electrode 230 is connected to the light-emitting stacked layer 220 through the fourth via hole H4 and the first via hole H1. In some other examples, as shown in FIG. 5, the reflective layer 270 covers the first via hole H1 and extends into the first via hole H7 to be connected to the light-emitting stacked layer 220. The second electrode 230 is connected to the light-emitting stacked layer 220 through the reflective layer 270.

It will be noted that a material of the reflective layer 270 includes a reflective metal. For example, the material of the reflective layer 270 includes at least one of titanium, platinum, or aluminum. For example, the reflective layer 270 includes a stacked-layer structure of a titanium layer, an aluminum layer, and a titanium layer.

In some embodiments, referring to FIG. 3, the light-emitting substrate 110 further includes a first planarization layer 60, and the first planarization layer 60 is disposed on a side of the second electrode 230 close to the light-emitting stacked layer 220. For example, the first planarization layer 60 is disposed between the second electrode 230 and the reflective layer 270 to play a role of planarization, which is conducive to improving the height uniformity of the plurality of light-emitting devices 21.

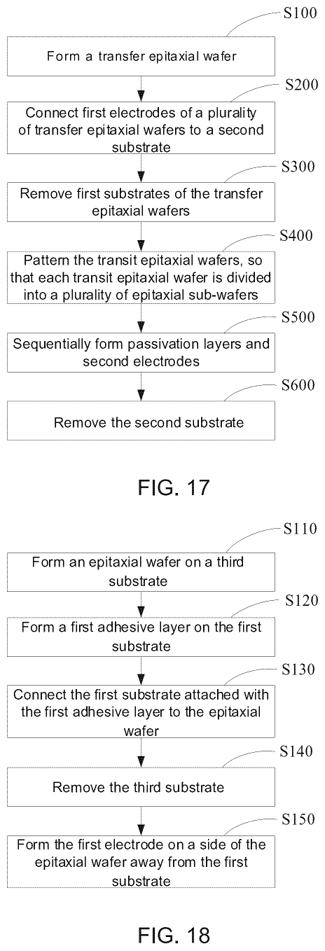

Some embodiments of the present disclosure further provide a method for manufacturing a light-emitting device 21. Referring to FIG. 17, the method includes S100 to S600.

In S100, a transfer epitaxial wafer 500 is formed.

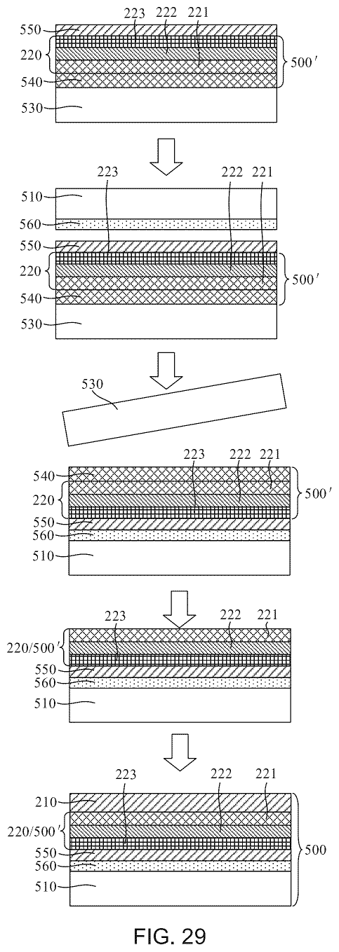

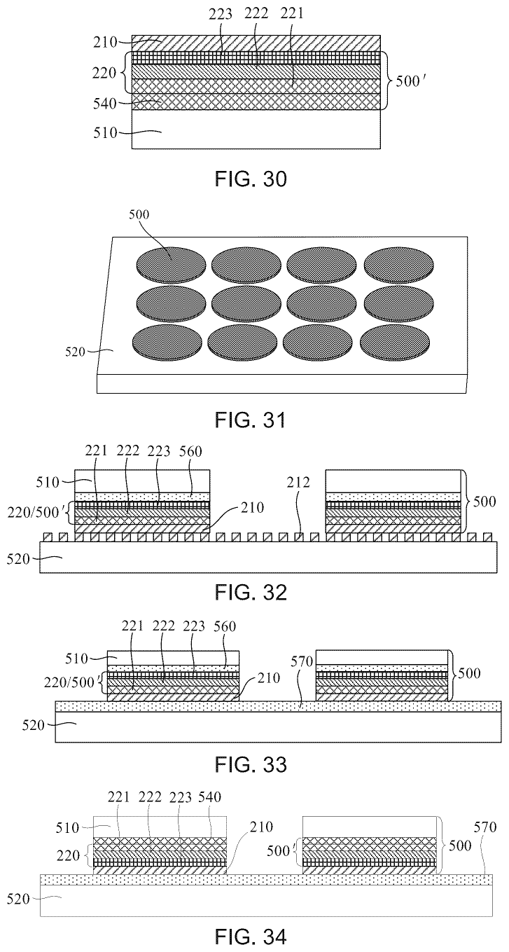

In the above step, referring to FIGS. 29 and 30, the transfer epitaxial wafer 500 includes a first substrate 510, a light-emitting stacked layer 220 and a first electrode 210, and the first electrode 210 and the light-emitting stacked layer 220 are sequentially stacked on the first substrate 510.

It will be noted that a material of the first substrate 510 includes a semiconductor material. For example, the material of the first substrate 510 includes at least one of monocrystalline silicon, polycrystalline silicon, silicon carbide, sapphire, gallium arsenide, aluminum nitride or zinc oxide.

In some embodiments, referring to FIG. 18, the step S100 includes steps S110 to S150.

In S110, an epitaxial wafer 500′ is formed on a third substrate 530.

In the above step, as shown in FIG. 29, the epitaxial wafer 500′ includes a light-emitting stacked layer 220; and the light-emitting stacked layer 220 includes a quantum well layer 222, and a first semiconductor doped layer 221 and a second semiconductor doped layer 223 that are respectively disposed on two opposite sides of the quantum well layer 222. The epitaxial wafer 500′ may further include a buffer layer 540, and the buffer layer 540 is disposed between the third substrate 530 and the light-emitting stacked layer 220.

It will be noted that a material of the third substrate 530 includes a semiconductor material. For example, the material of the third substrate 530 includes at least one of single crystal silicon, polycrystalline silicon, silicon carbide, sapphire, gallium arsenide, aluminum nitride and zinc oxide. A material of the buffer layer 540 may include gallium nitride.

In addition, as shown in FIG. 29, after the epitaxial wafer 500′ is formed, a fourth electrode 550 may be formed on a side of the epitaxial wafer 500′ away from the third substrate 530. A material of the fourth electrode 550 includes a transparent metal material. For example, the material of the fourth electrode 550 includes indium tin oxide and/or indium zinc oxide, so as to improve the current spreading and the current diffusion effect, and in turn to improve the light-emitting efficiency.

In S120, a first adhesive layer 560 is formed on the first substrate 510.

In the above step, as shown in FIG. 29, the first adhesive layer 560 may be formed on the first substrate 510 by a coating process. A material of the first adhesive layer 560 includes an organic material. For example, the material of the first adhesive layer 560 includes polyimide.

It will be noted that, a thickness of the first adhesive layer 560 is in a range of 1 μm to 5 μm. For example, the thickness of the first adhesive layer 560 is any one of 1 μm, 1.5 μm, 2 μm, 2.5 μm, 3 μm, 3.5 μm, 4 μm, 4.5 μm, and 5 μm.

In S130, the first substrate 510 attached with the first adhesive layer 560 is connected to the epitaxial wafer 500′.

In the above step, as shown in FIG. 29, two sides of the first substrate 510 and the third substrate 530 facing away from each other may be pressed by a pressing process, so that the epitaxial wafer 500′ on the third substrate 530 is adhered and fixed to the first substrate 510 through the first adhesive layer 560.

In S140, the third substrate 530 is removed.

In the above step, as shown in FIG. 29, the third substrate 530 may be removed by using at least one of an etching process, a planarization process or a mechanical exfoliation process. For example, the third substrate 530 is removed by using a wet etching process.

As shown in FIG. 29, in the case where the epitaxial wafer 500′ includes a buffer layer 540, after the third substrate 530 is removed, the buffer layer 540 may also be removed to expose the light-emitting stacked layer 220. Here, whether the light-emitting stacked layer 220 is exposed may be determined by an energy dispersive X-ray spectroscopy measuring elements included in exposed film layer(s) and relative amounts of the elements.

It will be noted that the process of removing the buffer layer 540 may be the same as or different from the process of removing the third substrate 530, which will not be specifically limited in the embodiments of the present disclosure.

Among the first semiconductor doped layer 221 and the second semiconductor doped layer 223, one is an N-type doped semiconductor layer, and the other is a P-type doped semiconductor layer. For example, the first semiconductor doped layer 221 is an N-type doped semiconductor layer, and the second semiconductor doped layer 223 is made of P-type doped gallium nitride. The material of the quantum well layer 222 includes gallium nitride and/or indium gallium nitride.

For example, the first semiconductor doped layer 221 is an N-type doped semiconductor layer, and the second semiconductor doped layer 223 is made of P-type doped gallium nitride. On this basis, the buffer layer 540 is removed so that the first semiconductor doped layer 221 is exposed. In this case, it is determined by determining whether the exposed film layer includes silicon and the relative amount of silicon. Elements of film layers in a direction from the third substrate 530 to the first substrate 510 measured by the energy dispersive X-ray spectroscopy are shown in Table 1 below.

As shown in Table 1, in a direction from the first substrate 510 to the epitaxial wafer 500′, there are the first substrate 510, the buffer layer 540, the first semiconductor doped layer 221, the quantum well layer 222 and the second semiconductor doped layer 223 in sequence.

The material of the first substrate 510 includes sapphire and has no doped ions. The material of the buffer layer 540 includes gallium nitride and has no doped ions. The material of the first semiconductor doped layer 221 includes gallium nitride and is doped with silicon (Si), and the dopant concentration may be in a range of 6×18¹⁰ cm⁻³ to 8×18¹⁰ cm⁻³. The material of the second semiconductor doped layer 223 includes gallium nitride and is doped with magnesium (Mg), and the dopant concentration may be in a range of 1×18¹⁹ cm⁻³ to 8×18²⁰ cm⁻³. The material of the quantum well layer 222 includes a light-emitting material, such as gallium nitride and/or indium gallium nitride, and the doped ions and dopant concentration may be set according to different light-emitting colors. For example, the quantum well layer 222 excites blue light, the quantum well layer 222 may be doped with indium, a light-emitting layer in the middle may be doped with silicon, and the dopant concentration of silicon may be 1×18¹⁸ cm⁻³.

It will be noted that other film layers may be provided between the buffer layer 540 and the first semiconductor doped layer 221, between the first semiconductor doped layer 221 and the quantum well layer 222, and between the quantum well layer 222 and the second semiconductor doped layer 223, so as to facilitate the sequential growth of the first semiconductor doped layer 221, the quantum well layer 222 and the second semiconductor doped layer 223. The embodiments of the present disclosure are not specifically limited thereto.

TABLE 1

| Film layer | Material | Dopant |
|---|---|---|
| Second semiconductor | Gallium nitride | Mg |
| doped layer | | |
| Quantum well layer | Light-emitting | — |
| | material | |
| First semiconductor | Gallium nitride | Si |
| doped layer | | |
| Buffer layer | Gallium nitride | None |
| First substrate | Sapphire | None |

In S150, the first electrode 210 is formed on a side of the epitaxial wafer 500′ away from the first substrate 510.

In the above step, as shown in FIG. 29, the first electrode 210 may be formed on the side of the epitaxial wafer 500′ away from the first substrate 510 by using a thin film deposition process. The thin film deposition process includes any one of chemical vapor deposition (CVD), physical vapor deposition (PVD), and atomic layer deposition (ALD).

It will be noted that after S150, the first electrode 210 may be subjected to a high-temperature annealing process to improve the crystallinity of the first electrode 210.

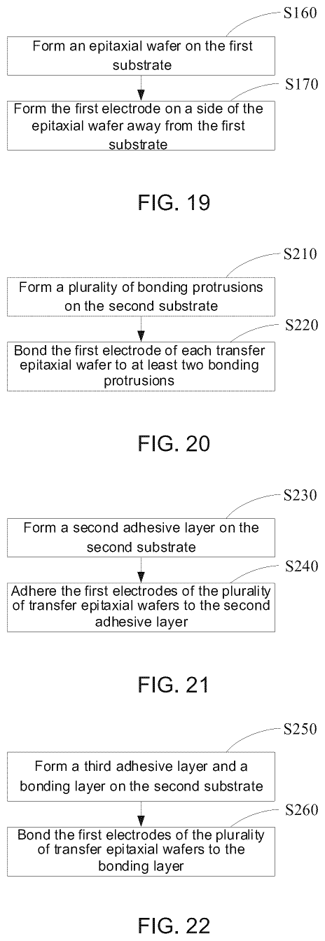

In some other embodiments, referring to FIG. 19, the above S100 includes S160 to S170.

In S160, an epitaxial wafer 500′ is formed on the first substrate 510.

In the above step, as shown in FIG. 30, the epitaxial wafer 500′ includes a light-emitting stacked layer 220. The epitaxial wafer 500′ may further include a buffer layer 540, and the buffer layer 540 is disposed between the first substrate 510 and the light-emitting stacked layer 220. It will be noted that a material of the buffer layer 540 may include gallium nitride.

In S170, the first electrode 210 is formed on a side of the epitaxial wafer 500′ away from the first substrate 510.

In the above step, as shown in FIG. 30, the first electrode 210 may be formed on the side of the epitaxial wafer 500′ away from the first substrate 510 by using a thin film deposition process. The thin film deposition process includes any one of chemical vapor deposition (CVD), physical vapor deposition (PVD), and atomic layer deposition (ALD).

In S200, first electrodes 210 of a plurality of transfer epitaxial wafers 500 are connected to a second substrate 520.

In the above step, as shown in FIGS. 31 to 35, the plurality of transfer epitaxial wafers 500 are arranged at intervals on the second substrate 520. The plurality of transfer epitaxial wafers 500 may be arranged in an array.

In some embodiments, referring to FIG. 20, S200 includes S210 to S220.

In S210, a plurality of bonding protrusions 212 are formed on the second substrate 520.

In the above step, as shown in FIG. 32, a whole layer of transparent metal material may be formed by using a thin film deposition process, and then it is patterned by wet etching and/or dry etching to form the plurality of bonding protrusions 212. The plurality of bonding protrusions 212 may be arranged in an array on the second substrate 520.

It will be noted that a thickness of the bonding protrusion 212 is in a range of 0.1 μm to 0.3 μm. For example, the thickness of the bonding protrusion 212 is any one of 0.1 μm, 0.15 μm, 0.2 μm, 0.25 μm, and 0.3 μm.

In S220, the first electrode 210 of each transfer epitaxial wafer 500 is bonded to at least two bonding protrusions 212.

In the above step, as shown in FIG. 32, the transfer epitaxial wafer 500 and the second substrate 520 are re-crystallized and nucleated through the first electrode 210 and at least two bonding protrusions 212, thus being hard-bonded. In this way, the connection strength between the transfer epitaxial wafer 500 and the second substrate 520 is relatively large, and the bonding protrusions 212 may be directly disconnected by mechanical pulling to achieve detachment.

In this case, in the subsequent process, the light-emitting device 21 mentioned in some of the above embodiments may be formed. In the light-emitting device 21, the first electrode 210 includes an electrode body 211 and a plurality of bonding protrusions 212, and the plurality of bonding protrusions 212 are arranged at intervals on a side of the electrode body 211.

The subsequently formed passivation layer 240 includes a first passivation portion 241 and a second passivation portion 242. The first passivation portion 241 covers a surface of the light-emitting stacked layer 220 away from the first electrode 210. The first passivation portion 241 is provided therein with a first via hole H1. The second electrode 230 is connected to the light-emitting stacked layer 220 through the first via hole H1. The second passivation portion 242 covers at least part of sidewalls of the light-emitting stacked layer 220 and the electrode body 211.

In some other embodiments, referring to FIG. 21, S200 includes S230 to S240.

In S230, a second adhesive layer 570 is formed on the second substrate 520.

In the above step, as shown in FIGS. 33 and 34, the second adhesive layer 570 may be formed on the second substrate 520 by a coating process. A material of the second adhesive layer 570 includes an organic material. For example, the material of the second adhesive layer 570 includes polyimide.

It will be noted that a thickness of the second adhesive layer 570 is in a range of 1 μm to 5 μm. For example, the thickness of the second adhesive layer 570 is any one of 1 μm, 1.5 μm, 2 μm, 2.5 μm, 3 μm, 3.5 μm, 4 μm, 4.5 μm, and 5 μm.

In S240, the first electrodes 210 of the plurality of transfer epitaxial wafers 500 are adhered to the second adhesive layer 570.

In the above step, as shown in FIGS. 33 and 34, two sides of the first substrate 510 and the second substrate 520 facing away from each other may be pressed by a pressing process, so that the transfer epitaxial wafers 500 on the first substrate 510 is adhered and fixed to the second substrate 520 through the second adhesive layer 570.

In this case, in the subsequent process, the light-emitting device 21 mentioned in some other of the above embodiments may be formed. In the light-emitting device 21, the thickness of the first electrode 210 is in a range of 0.1 μm to 0.3 μm. For example, the thickness of the first electrode 210 is any one of 0.1 μm, 0.12 μm, 0.14 μm, 0.15 μm, 0.18 μm, 0.2 μm, 0.24 μm, 0.25 μm, 0.28 μm and 0.3 μm. That is, the first electrodes 210 are in a conductive layer formed by one thin film deposition process.

The subsequently formed passivation layer 240 includes a first passivation portion 241 and a second passivation portion 242. The first passivation portion 241 covers a surface of the light-emitting stacked layer 220 away from the first electrode 210. The first passivation portion 241 is provided therein with a first via hole H1. The second electrode 230 is connected to the light-emitting stacked layer 220 through the first via hole H1. The second passivation portion 242 covers the sidewall of the light-emitting stacked layer 220 and extends to a side of the light-emitting stacked layer 220 away from the second electrode 230. A distance between a portion of the second passivation portion 242 exceeding the light-emitting stacked layer 220 and the light-emitting stacked layer 220 is greater than the thickness of the first electrode 210.

In yet some other embodiments, referring to FIG. 22, S200 includes S250 to S260.

In S250, a third adhesive layer 580 and a bonding layer 590 are formed on the second substrate 520.

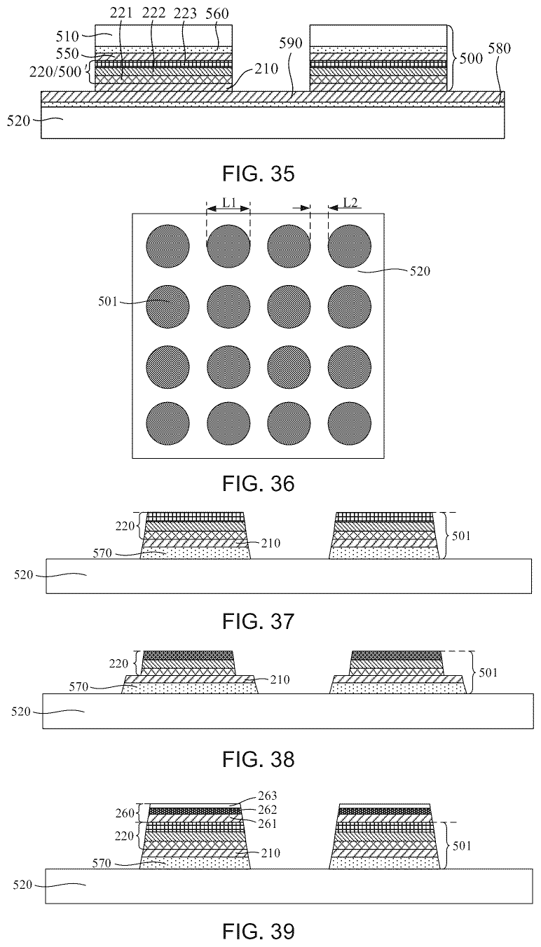

In the above step, as shown in FIG. 35, the third adhesive layer 580 is located between the bonding layer 590 and the second substrate 520. The third adhesive layer 580 may be formed on the first substrate 510 by using a coating process. The bonding layer 590 may be formed on a side of the third adhesive layer 580 away from the second substrate 520 by using a thin film deposition process.

A material of the bonding layer 590 includes a transparent metal material. For example, the material of the bonding layer 590 includes indium tin oxide and/or indium zinc oxide. A material of the third adhesive layer 580 includes an organic material. For example, the material of the third adhesive layer 580 includes polyimide.

In addition, a thickness of the bonding layer 590 is in a range of 0.1 μm to 0.3 μm. For example, the thickness of the bonding layer 590 is any one of 0.1 μm, 0.15 μm, 0.2 μm, 0.25 μm, and 0.3 μm. A thickness of the third adhesive layer 580 is in a range of 0.1 μm to 0.5 μm. For example, the thickness of the third adhesive layer 580 is any one of 0.1 μm, 0.15 μm, 0.2 μm, 0.25 μm, 0.3 μm, 0.35 μm, 0.4 μm, 0.45 μm, and 0.5 μm.

It will be noted that when the first adhesive layer 560, the second adhesive layer 570, the third adhesive layer 580 and the fourth adhesive layer 630 are each made of polyimide, the proportions of the elements contained in the polyimide may be different, so that the thicknesses of the film layers formed by the coating process are different.

In this case, in the subsequent process, the light-emitting device 21 mentioned in some other of the above embodiments may be formed. In the light-emitting device 21, the first electrode 210 is formed by bonding the bonding layer 590 in S250 and the first electrode 210 of the transfer epitaxial wafer 500. The thickness of the first electrode 210 is twice the thickness of the first electrode 210 of the light-emitting device 21 in other embodiments. For example, the thickness of the first electrode 210 is in a range of 0.2 μm to 0.6 μm. For example, the thickness of the first electrode 210 is any one of 0.2 μm, 0.25 μm, 0.3 μm, 0.35 μm, 0.4 μm, 0.45 μm, 0.5 μm, 0.55 μm, and 0.6 μm. That is, the first electrode 210 of the light-emitting device 21 formed in this embodiment is formed by bonding conductive layers formed by two thin film deposition processes.

The subsequently formed passivation layer 240 includes a first passivation portion 241 and a second passivation portion 242. The first passivation portion 241 covers a surface of the light-emitting stacked layer 220 away from the first electrode 210. The first passivation portion 241 is provided therein with a first via hole H1. The second electrode 230 is connected to the light-emitting stacked layer 220 through the first via hole H1. The second passivation portion 242 covers the sidewall of the light-emitting stacked layer 220 and extends to a side of the light-emitting stacked layer 220 away from the second electrode 230. A distance between a portion of the second passivation portion 242 exceeding the light-emitting stacked layer 220 and the light-emitting stacked layer 220 is greater than the thickness of the first electrode 210.

In S260, the first electrodes 210 of the plurality of transfer epitaxial wafers 500 are bonded to the bonding layer 590.

In the above step, as shown in FIG. 35, the transfer epitaxial wafer 500 and the second substrate 520 are re-crystallized and nucleated through the first electrode 210 and the bonding layer 590, thus being hard-bonded. In this way, the connection strength between the transfer epitaxial wafer 500 and the second substrate 520 is relatively large, and may be detached through the third adhesive layer 580.

In S300, the first substrates 510 of the transfer epitaxial wafers 500 are removed.

In the above step, referring to FIGS. 32 to 39, the first substrates 510 may be removed by at least one of laser debonding, thermal slide debonding, chemical debonding or mechanical debonding.

In some examples, S100 includes S110 to S150, and a laser with a wavelength of 355 nm passes through the first substrate 510 and is absorbed by the first adhesive layer 560, causing the interface between the first substrate 510 and the first adhesive layer 560 to be eroded, thereby removing the first substrate 510.

In some other examples, S100 includes S160 to S170, and a laser with a wavelength of 266 nm passes through the first substrate 510 and is absorbed by the material of the buffer layer 540, causing the interface between the first substrate 510 and the buffer layer 540 to be eroded, thereby removing the first substrate 510. Of course, the first substrate 510 may also be removed by wet etching, which is not specifically limited in the embodiments of the present disclosure.

In the case where the epitaxial wafer 500′ includes a buffer layer 540, after the first substrate 510 is removed, the buffer layer 540 may also be removed to expose the light-emitting stacked layer 220. Here, whether the light-emitting stacked layer 220 is exposed may be determined by an energy dispersive X-ray spectroscopy measuring elements included in exposed film layer(s) and relative amounts of the elements.

It will be noted that the process of removing the buffer layer 540 may be the same as or different from the process of removing the first substrate 510, which will not be specifically limited in the embodiments of the present disclosure.

In S400, the transit epitaxial wafers 500 are patterned, so that each transit epitaxial wafer 500 is divided into a plurality of epitaxial sub-wafers 501.

In the above step, as shown in FIGS. 37 to 39, each epitaxial sub-wafer 501 includes a light-emitting stacked layer 220 and a first electrode 210. Each epitaxial sub-wafer 501 forms a corresponding light-emitting device 21 in the subsequent process. That is to say, one transfer epitaxial wafer 500 may form a plurality of light-emitting devices 21, thereby improving the manufacturing efficiency and reducing the manufacturing costs.

It will be noted that the first electrode 210 of each epitaxial sub-wafer 501 is bonded to at least two bonding protrusions 212. Therefore, on the basis of high bonding strength, the bonding protrusions 212 are directly disconnected by mechanical pulling to achieve the subsequently formed light-emitting devices 21 being detached from the second substrate 520. Orthogonal projections of two adjacent epitaxial sub-wafers 501 on the second substrate 520 may each be in a shape of any one of a circle, an ellipse and a square. That is, a shape of an orthogonal projection of a subsequently formed light-emitting device 21 on the second substrate 520 may be any one of a circle, an ellipse and a square.

Referring to FIG. 36, a distance L2 between the orthogonal projections of two adjacent epitaxial sub-wafers 501 on the second substrate 520 is in a range of 2 μm to 20 μm. For example, the distance L2 between the orthogonal projections of two adjacent epitaxial sub-wafers 501 on the second substrate 520 is any one of 2 μm, 4 μm, 6 μm, 9 μm, 10 μm, 13 μm, 15 μm, 18 μm and 20 μm.

In addition, referring to FIG. 45, a radial dimension L1 of each epitaxial sub-wafer 501 is in a range of 2 μm to 20 μm. For example, the radial dimension L1 of each epitaxial sub-wafer 501 is any one of 2 μm, 4 μm, 6 μm, 9 μm, 10 μm, 13 μm, 15 μm, 18 μm and 20 μm.

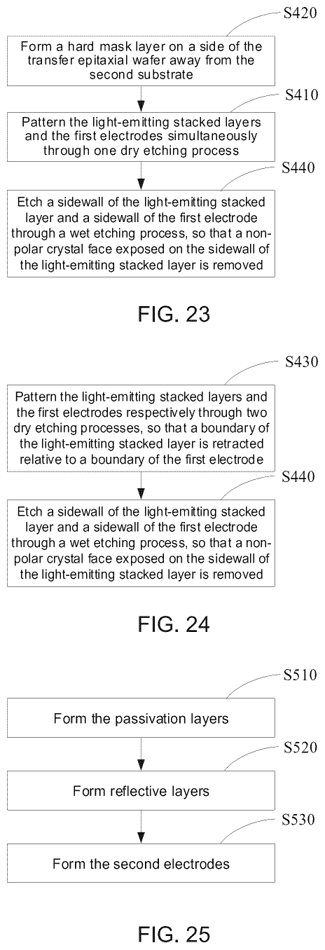

In some embodiments, referring to FIG. 23, S400 includes S410.

In S410, the light-emitting stacked layers 220 and the first electrodes 210 are patterned simultaneously through one dry etching process.

In the above step, referring to FIGS. 37 and 39, the light-emitting stacked layers 220 and the first electrodes 210 may be patterned through one etching by using a mask. A material of the mask includes photoresist.

In this case, a slope angle of the light-emitting stacked layer 220 is greater than or equal to 60°. In this case, a slope angle of a side surface of the light-emitting stacked layer 220 is relatively large, so that the second electrode 230 and the light-emitting stacked layer 220 have a relatively large contact area, which increases the light-emitting area. Moreover, the contact area between the passivation layer 240 and an upper surface of the light-emitting stacked layer 220 is larger, providing better coverage and adhesion.

In this case, in the subsequent process, the light-emitting device 21 mentioned in some of the above embodiments may be formed. In the light-emitting device 21, the subsequently formed passivation layer 240 includes a first passivation portion 241 and a second passivation portion 242. The first passivation portion 241 covers a surface of the light-emitting stacked layer 220 away from the first electrode 210. The first passivation portion 241 is provided therein with a first via hole H1. The second electrode 230 is connected to the light-emitting stacked layer 220 through the first via hole H1. The second passivation portion 242 covers the sidewall of the light-emitting stacked layer 220 and extends to a side of the light-emitting stacked layer 220 away from the second electrode 230. A distance between a portion of the second passivation portion 242 exceeding the light-emitting stacked layer 220 and the light-emitting stacked layer 220 is greater than the thickness of the first electrode 210.

On this basis, as shown in FIG. 23, before S410, S400 may further include S420.

In S420, a hard mask layer 260 is formed on a side of the transfer epitaxial wafer 500 away from the second substrate 520.

In the above step, as shown in FIG. 39, the hard mask layer 260 covers the surface of the light-emitting stacked layer 220 away from the first electrode 210 to reduce the damage of the surface of the light-emitting stacked layer 220 away from the first electrode 210 through the etching process in S410. The hard mask layer 260 may be composed of a plurality of layers that are stacked. For example, the hard mask layer 260 includes a photoresist layer 263, a silicon oxide layer 262, and an indium tin oxide layer 261 that are stacked in sequence, and the indium tin oxide layer 261 is closer to the light-emitting stacked layer 220.

In this case, considering the protection effect of the hard mask layer 260, the slope angle of the light-emitting stacked layer 220 may be greater than or equal to 80°. In this case, it may be possible to further increase the slope angle of the side surface of the light-emitting stacked layer 220, increase the contact area between the second electrode 230 and the light-emitting stacked layer 220, and in turn increase the light-emitting area. Moreover, the contact area between the passivation layer 240 and an upper surface of the light-emitting stacked layer 220 is larger, providing better coverage and adhesion.

In some other embodiments, referring to FIG. 24, S400 includes S430.

In S430, the light-emitting stacked layers 220 and the first electrodes 210 are respectively patterned through two dry etching processes, so that a boundary of the light-emitting stacked layer 220 is retracted relative to a boundary of the first electrode 210.

In the above step, as shown in FIG. 38, the light-emitting stacked layers 220 may be patterned through one etching by using a mask, and the first electrodes 210 may be patterned through one etching by using a mask. A material of the mask includes photoresist.

In some embodiments, as shown in FIG. 38, a distance between the boundary of the light-emitting stacked layer 220 and the boundary of the first electrode 210 is greater than or equal to 1 μm, thereby facilitating the subsequent process in which the passivation layer 240 (see FIG. 9) and/or the reflective layer 270 (see FIG. 9) is formed on an edge portion of the first electrode 210 exceeding the light-emitting stacked layer 220.

In this case, in the subsequent process, the light-emitting device 21 mentioned in some other of the above embodiments may be formed. In the light-emitting device 21, the subsequently formed passivation layer 240 includes a first passivation portion 241 and a second passivation portion 242. The first passivation portion 241 covers a surface of the light-emitting stacked layer 220 away from the first electrode 210. The first passivation portion 241 is provided therein with a first via hole H1. The second electrode 230 is connected to the light-emitting stacked layer 220 through the first via hole H1. The second passivation portion 242 covers the sidewall of the light-emitting stacked layer 220, and at least part of an edge of the first electrode 210 exceeds the second passivation portion 242.

In some examples, as shown in FIG. 9, a circumferential boundary of the first electrode 210 exceeds the passivation layer 240. That is, the second passivation portion 242 is located on an edge portion of the first electrode 210 that exceeds the light-emitting stacked layer 220, and an outer boundary of the second passivation portion 242 is retracted relative to the boundary of the first electrode 210. In this way, during the process of manufacturing the light-emitting device 21, the passivation layer 240 are not in contact with the substrate (the second substrate 520 as mentioned below), which facilitates the light-emitting device 21 being separated from the substrate (the second substrate 520 as mentioned below).

In some other examples, as shown in FIGS. 10 and 11, a part of the circumferential boundary of the first electrode 210 exceeds the passivation layer 240.

For example, the second passivation portion 242 includes a first sub-portion 2421 and a second sub-portion 2422 that are connected along a circumferential direction of the light-emitting stacked layer 220; an edge portion of the first electrode 210 corresponding to the first sub-portion 2421 does not exceed the passivation layer 240; and an edge portion of the first electrode 210 corresponding to the second sub-portion 2422 exceeds the passivation layer 240, that is, exceeds the second passivation portion 242.

The first sub-portion 2421 covers a part of the sidewall of the light-emitting stacked layer 220 and a part of the sidewall of the first electrode 210, and an end of the first sub-portion 2421 away from the second electrode 230 is flush with a surface of the first electrode 210 away from the second electrode 230. The second sub-portion 2422 covers another part of the sidewall of the light-emitting stacked layer 220, and is located on an edge portion of the first electrode 210 that exceeds the light-emitting stacked layer 210.

In the case where S400 includes S410 or S430, the dry etching process may result in a non-polar crystal face of the first semiconductor doped layer 221 and/or the second semiconductor doped layer 223 in the light-emitting stacked layer 220.

In light of this, as shown in FIGS. 23 and 24, the above S400 further includes S440.

In S440, the sidewall of the light-emitting stacked layer 220 and the sidewall of the first electrode 210 are etched through a wet etching process, so that a non-polar crystal face exposed on the sidewall of the light-emitting stacked layer 220 is removed.

In the above step, referring to FIG. 15, since the materials of the film layers in the light-emitting stacked layer 220 are inconsistent, the etching rates are different for the same etchant. After S440, the sidewall of the light-emitting stacked layer 220 is of a stepped structure S; and the circumferential boundary of the light-emitting stacked layer 220 is indented in a stepped manner along a direction from the second electrode 230 to the first electrode 210.

For example, the light-emitting stacked layer 220 includes a quantum well layer 222, and a first semiconductor doped layer 221 and a second semiconductor doped layer 223 that are respectively disposed on two opposite sides of the quantum well layer 222. On this basis, the first semiconductor doped layer 221, the quantum well layer 222 and the second semiconductor doped layer 223 each form a single step.

It will be noted that, since the dopant concentrations at different positions in the first semiconductor doped layer 221 and the second semiconductor doped layer 223 may be different, the first step S1 and the third step S3 may each include a plurality of sub-steps, which is not specifically limited in the embodiments of the present disclosure.

In S500, passivation layers 240 and second electrodes 230 are sequentially formed.

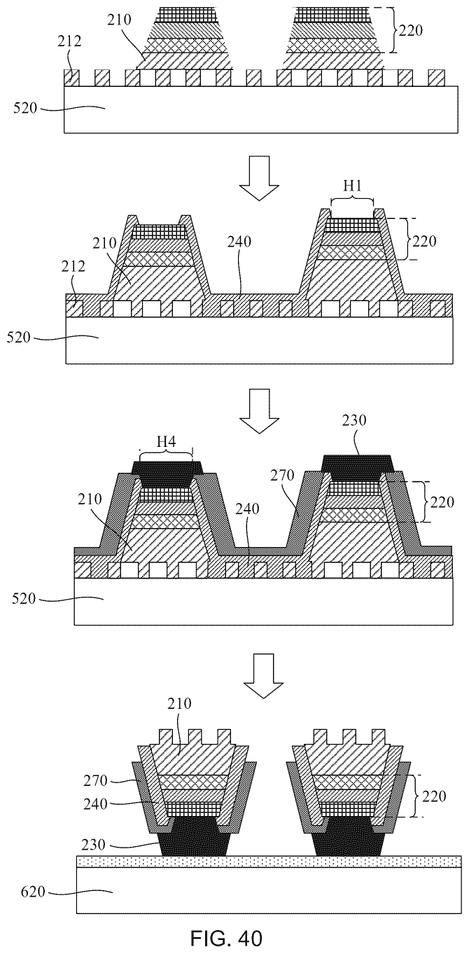

In the above step, referring to FIGS. 14 and 40, the passivation layer 240 includes a first passivation portion 241 and a second passivation portion 242. The first passivation portion 241 covers a surface of the light-emitting stacked layer 220 away from the first electrode 230. The first passivation portion 241 is provided therein with a first via hole H1. The second electrode 230 is connected to the light-emitting stacked layer 220 through the first via hole H1.

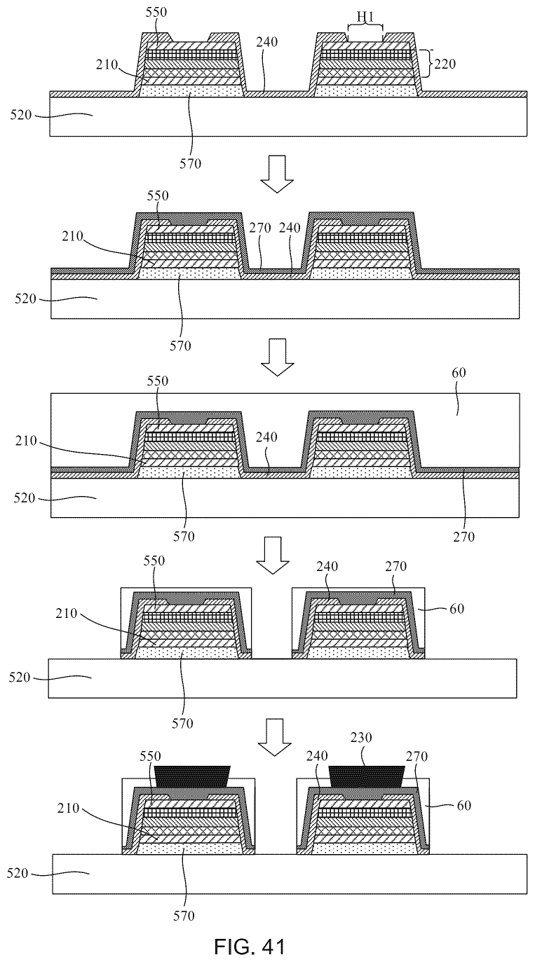

Referring to FIG. 41, during the process of S500, a reflective layer 270 and a first planarization layer 60 may further be formed. The reflective layer 270 is disposed on a side of the passivation layer 240 away from the light-emitting stacked layer 220, and the first planarization layer 60 is disposed on a side of the reflective layer 270 away from the light-emitting stacked layer 220.

It will be noted that a material of the first planarization layer 60 includes optical adhesive and/or organic siloxane. A thickness of the first planarization layer 60 is in a range of 1 μm to 5 μm. For example, the thickness of the first planarization layer 60 is any one of 1 μm, 1.5 μm, 2 μm, 2.5 μm, 3 μm, 3.5 μm, 4 μm, 4.5 μm, and 5 μm.

In addition, the passivation layer 240, the reflective layer 270 and the first planarization layer 60 all need to be patterned. The passivation layer 240, the reflective layer 270 and the first planarization layer 60 may be patterned simultaneously in the same process, or may be patterned separately. For example, the passivation layer 240, the reflective layer 270, and the first planarization layer 60 are patterned simultaneously through a wet etching process and/or dry etching process.

In the case where S400 includes S410, referring to FIGS. 6 and 41, the second passivation portion 242 of the passivation layer 240 covers the sidewall of the light-emitting stacked layer 220 and the sidewall of the first electrode 210, and extends to a side of the first electrode 210 away from the second electrode 230. A distance between a boundary of an orthogonal projection of the second passivation portion 242 on the second substrate 520 and a boundary of an orthogonal projection of the first electrode 210 on the second substrate 520 is in a range of 0 μm to 0.6 μm, thereby facilitating the detachment of the light-emitting device 21.

In the case where S400 includes S430, among at least two adjacent light-emitting devices 21, one may be a first light-emitting device 201, and another may be a second light-emitting device 202. Alternatively, among at least two adjacent light-emitting devices 21, one is a third light-emitting device 203, and another is a fourth light-emitting device 204.

In some embodiments, referring to FIG. 12, among at least two adjacent light-emitting devices 21, one is a first light-emitting device 201, and another is a second light-emitting device 202. After S430, as shown in FIG. 25, S500 includes S510 to S530.

In S510, the passivation layers 240 are formed.

In the above step, as shown in FIGS. 9, 10 and 12, the passivation layer 240 may be formed by using a thin film deposition process and then a patterning process. The passivation layer 240 of the first light-emitting device 201 is a first passivation layer 2410, and the passivation layer 240 of the second light-emitting device 202 is a second passivation layer 2420.

It will be noted that the passivation layer 240 may be formed through two thin film deposition processes; in the first process, atomic layer deposition is used to deposit silicon oxide to achieve a good anti-oxidation effect; in the second process, chemical vapor deposition is used to deposit silicon dioxide, silicon oxide and silicon nitride, or silicon dioxide and aluminum oxide to improve the manufacturing efficiency.

As shown in FIGS. 9, 10 and 12, the second passivation portion 242 of the first passivation layer 2410 is retracted relative to the boundary of the first electrode 210. The second passivation portion 242 of the second passivation layer 2420 includes a first sub-portion 2421 and a second sub-portion 2422; the first sub-portion 2421 covers a part of the sidewall of the light-emitting stacked layer 220 and a part of the sidewall of the first electrode 210; and the second sub-portion 2422 covers another part of the sidewall of the light-emitting stacked layer 220 and is located on an edge portion of the first electrode 210 that exceeds the light-emitting stacked layer 220.

In S520, reflective layers 270 are formed.

In the above step, as shown in FIGS. 9, 10 and 12, the reflective layer 270 may be formed by using a thin film deposition process and then a patterning process. The reflective layer 270 is disposed on a side of the passivation layer 240 away from the light-emitting stacked layer 220. The reflective layer 270 of the first light-emitting device 201 is a first reflective layer 2710, and the reflective layer 270 of the second light-emitting device 202 is a second reflective layer 2720.

As shown in FIGS. 9, 10 and 12, a boundary of the first reflective layer 2710 is substantially flush with a boundary of the first passivation layer 2410; alternatively, at least a part of the boundary of the first reflective layer 2710 is retracted relative to the boundary of the first passivation layer 2410. The second reflective layer 2720 covers the first sub-portion 2421 of the second passivation layer 2420, and is connected to a portion of the first electrode 210 of the first light-emitting device 201 that exceeds the first passivation layer 2410.

It will be noted that, after S520, a first planarization layer 60 may be formed by a coating process. The first planarization layer 60 is disposed on a side of the reflective layer 270 away from the light-emitting stacked layer 220.

In S530, the second electrodes 230 are formed.

In the above step, as shown in FIGS. 9, 10 and 12, the second electrode 230 may be formed by using a thin film deposition process and then a patterning process. The second electrode 230 is disposed on the side of the reflective layer 270 away from the light-emitting stacked layer 220, and is connected to the reflective layer 270.

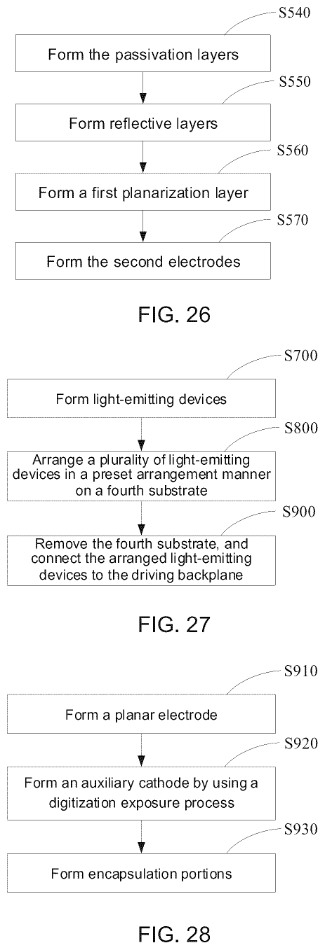

In some other embodiments, referring to FIG. 13, among at least two adjacent light-emitting devices 21, one is a third light-emitting device 203, and another is a fourth light-emitting device 204. After S430, as shown in FIG. 26, S500 includes S540 to S570.

In S540, the passivation layers 240 are formed.

In the above step, as shown in FIGS. 9, 11 and 13, the passivation layer 240 may be formed by using a thin film deposition process and then a patterning process. The passivation layer 240 of the third light-emitting device 203 is a third passivation layer 2430, and the passivation layer 240 of the fourth light-emitting device 204 is a fourth passivation layer 2440.

As shown in FIGS. 9, 11 and 13, the second passivation portion 242 of the third passivation layer 2430 is retracted relative to the boundary of the first electrode 210. The second passivation portion 242 of the fourth passivation layer 2440 includes a first sub-portion 2421 and a second sub-portion 2422, and the first sub-portion 2421 covers a part of the sidewall of the light-emitting stacked layer 220 and a part of the sidewall of the first electrode 210. The second sub-portion 2422 covers another part of the sidewall of the light-emitting stacked layer 220, and is located on an edge portion of the first electrode 210 that exceeds the light-emitting stacked layer 220.

In S550, reflective layers 270 are formed.

In the above step, as shown in FIGS. 9, 11 and 13, the reflective layer 270 may be formed by using a thin film deposition process and then a patterning process. The reflective layer 270 is disposed on a side of the passivation layer 240 away from the light-emitting stacked layer 220. An orthogonal projection of the reflective layer 270 on the driving backplane 10 is located within an orthogonal projection of the passivation layer 240 on the driving backplane 10. That is, a boundary of the reflective layer 270 is substantially flush with a boundary of the first passivation layer 2410; alternatively, at least a portion of the boundary of the reflective layer 270 is retracted relative to the boundary of the first passivation layer 2410.

In S560, a first planarization layer 60 is formed.

In the above step, as shown in FIGS. 9, 11 and 13, the first planarization layer 60 may be formed by using a coating process and then a patterning process. The first planarization layer 60 is disposed on a side of the reflective layer 270 away from the light-emitting stacked layer 220, and the first planarization layer 60 is provided therein with a third via hole H3.

In S570, the second electrodes 230 are formed.

In the above step, as shown in FIGS. 9, 11 and 13, the second electrode 230 may be formed by using a thin film deposition process and then a patterning process. The second electrode 230 is disposed on the side of the reflective layer 270 away from the light-emitting stacked layer 220.

The second electrode 230 of the third light-emitting device 203 is connected to a portion of the first electrode 210 of the fourth light-emitting device 204 that exceeds the passivation layer 240 through the third via hole H3.

Based on the above, S500 includes S510 to S530, or S500 includes S540 to S570. Thus, the light-emitting devices 21 connected in series may be directly formed, which may simplify the processes and reduce the manufacturing costs.

In S600, the second substrate 520 is removed.

In the case where S200 includes S210 and S220, as shown in FIG. 40, S600 may be performed using a mechanical exfoliation manner so that the passivation layer 240 and the bonding protrusions 212 are disconnected by pulling. In the case where the reflective layer 270 is formed in S500, when the passivation layer 240 and the bonding protrusions 212 are disconnected by pulling, the reflective layer 270 is also disconnected by pulling.

As shown in FIGS. 14 and 40, the second passivation portion 242 covers the sidewall of the light-emitting stacked layer 220 and the sidewall of the electrode body 211, and an end of the second passivation portion 242 away from the first passivation portion 241 is substantially flush with a surface of the electrode body 211 away from the first passivation portion 241. Alternatively, the second passivation portion 242 covers the sidewall of the light-emitting stacked layer 220 and a part of the sidewall of the electrode body 211; and an end of the second passivation portion 242 away from the first passivation portion 241 is located between a surface of the electrode body 211 away from the first passivation portion 241 and a surface of the electrode body 211 close to the first passivation portion 241.

As shown in FIGS. 14 and 40, the reflective layer 270 is substantially flush with an end of the second passivation portion 242 away from the second electrode 230; alternatively, an end of the reflective layer 270 away from the second electrode 230 is closer to the second electrode 230 than an end of the second passivation portion 242 away from the second electrode 230.

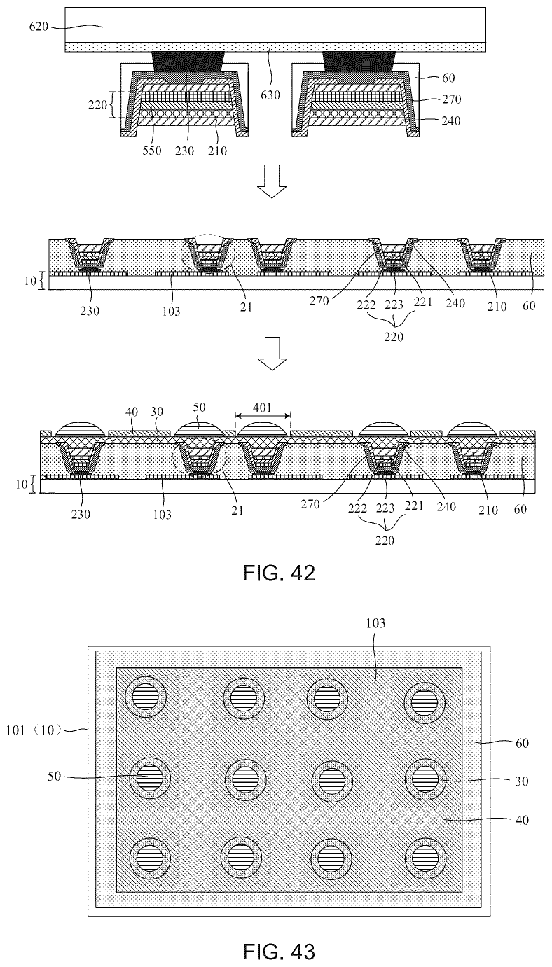

In the case where S200 includes S230 to S240 or S200 includes S250 to S260, as shown in FIGS. 41 and 42, S600 of removing the second substrate 520 may be performed by using at least one of laser debonding, thermal slide debonding, chemical debonding or mechanical debonding.

It will be noted that after the second substrate 520 is removed, the remaining second adhesive layer 570 or the third adhesive layer 580 may be removed by an ashing process. Considering that the ashing process may result in pits on the surface of the first electrode 210 away from the second electrode 230, a connection electrode 250 may be formed on the first electrode 210 to fill the surface of the first electrode 210 away from the second electrode 230, which facilitates the subsequent connection with other circuits (such as the planar electrode 30).

Some embodiments of the present disclosure further provide a method for manufacturing a light-emitting substrate 110, and as shown in FIG. 27, the method includes S700 to S900.

In S700, light-emitting devices 21 are formed.

In the above step, the light-emitting devices 21 are formed by using the method for manufacturing a light-emitting device as described in any of the above embodiments.

In S800, a plurality of light-emitting devices 21 are arranged in a preset arrangement manner on a fourth substrate 620.

In the above step, as shown in FIGS. 12, 13, and 42 to 45, the plurality of light-emitting devices 21 may be connected to the fourth substrate 620 through a fourth adhesive layer 630. For example, the fourth adhesive layer 630 is formed on the fourth substrate 620 by using a coating process. A material of the fourth adhesive layer 630 includes an organic material. For example, the material of the fourth adhesive layer 630 includes polyimide.

It will be noted that a thickness of the fourth adhesive layer 630 is in a range of 1 μm to 5 μm. For example, the thickness of the fourth adhesive layer 630 is any one of 1 μm, 1.5 μm, 2 μm, 2.5 μm, 3 μm, 3.5 μm, 4 μm, 4.5 μm, and 5 μm.

In addition, the arrangement manner of the plurality of light-emitting devices 21 varies. The preset arrangement manner may be set according to actual situations.

For example, the preset arrangement manner is a standard arrangement. That is, the plurality of light-emitting devices 21 include red light-emitting devices, blue light-emitting devices and green light-emitting devices, and are arranged in a plurality of rows and a plurality of columns; each row includes red light-emitting devices, blue light-emitting devices and green light-emitting devices that are arranged sequentially and cyclically; and light-emitting devices 21 in the same column emit light of the same color.

In S900, the fourth substrate 620 is removed, and the arranged light-emitting devices 21 are connected to the driving backplane 10.

In the above step, as shown in FIGS. 41 and 42, the fourth substrate 620 may be removed by at least one of laser debonding, thermal slide debonding, chemical debonding or mechanical debonding.

In some embodiments, referring to FIG. 28, the method for manufacturing the light-emitting substrate 110 further includes S910 to S930.

In S910, a planar electrode 30 is formed.

In the above step, as shown in FIGS. 41 and 42, the planar electrode 30 may be formed by using a thin film deposition process. The planar electrode 30 is disposed on a side of the light-emitting devices 21 away from the driving backplane 10, and is connected to the first electrodes 210 of the light-emitting devices 21.

In S920, an auxiliary cathode 40 is formed by using a digitization exposure process.

In the above step, as shown in FIGS. 41 and 42, the auxiliary electrode 40 is formed by a digitization exposure process, which may achieve high-precision morphology control. The auxiliary electrode 40 is disposed on a side of the planar electrode 30 away from the driving backplane 10, and is connected to the planar electrode 30, so as to reduce the resistance of transmitting the second voltage signal, reduce the voltage drop, and reduce the difference in the second voltage signal of the electronic components 20 at different positions, and in turn to improve the brightness uniformity of the light-emitting substrate 110.

In addition, as shown in FIGS. 41, 42 and 43, the auxiliary electrode 40 may be provided therein with a plurality of openings 401, an opening 401 exposes a light-emitting device 21, and a shape of an orthogonal projection of the opening 401 on the driving backplane 10 is the same as a shape of the orthogonal projection of the light-emitting device 21 on the driving backplane 10. In this way, the auxiliary electrode 40 may block light between the light-emitting devices 21 without adding a light-shielding layer, which is conducive to reducing a thickness of the display apparatus 1000.

In S930, encapsulation portions 50 are formed.

In the above step, as shown in FIGS. 41, 42 and 43, the encapsulation portions 50 may be formed by using a dispensing process. For example, the encapsulation portions 50 may be formed through spraying high thixotropic glue by a dispenser and then a curing process. An orthogonal projection of a single light-emitting device 21 on the driving backplane 10 is located within an orthogonal projection of a single encapsulation portion 50 on the driving backplane 10, so as to protect the light-emitting device 21.

The foregoing descriptions are merely specific implementation manners of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A light-emitting device, comprising:
a first electrode;
a light-emitting stacked layer disposed on a side of the first electrode and connected to the first electrode;
a second electrode disposed on a side of the light-emitting stacked layer away from the first electrode, the second electrode being configured to be connected to a driving backplane; and
a passivation layer including a first passivation portion and a second passivation portion, wherein the first passivation portion covers a surface of the light-emitting stacked layer away from the first electrode; the first passivation portion is provided therein with a first via hole, and the second electrode is connected to the light-emitting stacked layer through the first via hole; the second passivation portion covers a sidewall of the light-emitting stacked layer and extends to a side of the light-emitting stacked layer away from the second electrode; a distance between a portion of the second passivation portion exceeding the light-emitting stacked layer and the light-emitting stacked layer is greater than a thickness of the first electrode.

2. The light-emitting device according to claim 1, wherein the second passivation portion covers the sidewall of the light-emitting stacked layer and a sidewall of the first electrode, and extends to the side of the light-emitting stacked layer away from the second electrode.

3. The light-emitting device according to claim 2, further comprising:
a connection electrode disposed on a side of the first electrode away from the second electrode, wherein the connection electrode covers the first electrode and extends to a surface of the second passivation portion away from the first passivation portion.

4. The light-emitting device according to claim 1, wherein boundaries of two surfaces, facing away from each other, of the light-emitting stacked layer and the first electrode are connected to form a slope surface, and a slope angle of the slope surface is greater than or equal to 60°.

5. The light-emitting device according to claim 1, further comprising:
a hard mask layer disposed between a surface of the light-emitting stacked layer away from the first electrode and the passivation layer, wherein the hard mask layer is provided therein with a second via hole, and the second electrode is connected to the light-emitting stacked layer through the first via hole and the second via hole.

6. The light-emitting device according to claim 5, wherein boundaries of two surfaces, facing away from each other, of the light-emitting stacked layer and the first electrode are connected to form a slope surface, and a slope angle of the slope surface is greater than or equal to 80°.

7. The light-emitting device according to claim 1, wherein a thickness of the first electrode is in a range of 1000 Å to 6000 Å.

8. The light-emitting device according to claim 1, wherein the sidewall of the light-emitting stacked layer is of a stepped structure; and in a direction from the second electrode to the first electrode, a circumferential boundary of the light-emitting stacked layer is indented in a stepped manner.

9. The light-emitting device according to claim 1, further comprising:
a reflective layer disposed on a side of the passivation layer away from the light-emitting stacked layer.

10. A light-emitting device, comprising:
a first electrode;
a light-emitting stacked layer disposed on the first electrode and connected to the first electrode, wherein a boundary of the light-emitting stacked layer is retracted relative to a boundary of the first electrode;
a second electrode disposed on a side of the light-emitting stacked layer away from the first electrode, the second electrode being configured to be connected to a driving backplane; and
a passivation layer including a first passivation portion and a second passivation portion that are connected, wherein the first passivation portion covers a surface of the light-emitting stacked layer away from the first electrode; the first passivation portion is provided therein with a first via hole, and the second electrode is connected to the light-emitting stacked layer through the first via hole; the second passivation portion covers a sidewall of the light-emitting stacked layer; and at least part of an edge of the first electrode exceeds the second passivation portion.

11. The light-emitting device according to claim 10, wherein the second passivation portion is located on an edge portion of the first electrode that exceeds the light-emitting stacked layer, and an outer boundary of the second passivation portion is retracted relative to the boundary of the first electrode.

12. The light-emitting device according to claim 10, wherein the second passivation portion includes a first sub-portion and a second sub-portion that are connected along a circumferential direction of the light-emitting stacked layer; the first sub-portion covers a part of the sidewall of the light-emitting stacked layer and a part of a sidewall of the first electrode; the second sub-portion covers another part of the sidewall of the light-emitting stacked layer and is located on an edge portion of the first electrode that exceeds the light-emitting stacked layer; and the edge portion of the first electrode corresponding to the second sub-portion exceeds the second passivation portion.

13. A light-emitting device, comprising:
a first electrode including an electrode body and a plurality of bonding protrusions, wherein the plurality of bonding protrusions are arranged at intervals on a side of the electrode body;
a light-emitting stacked layer disposed on a side of the electrode body away from the bonding protrusions and connected to the electrode body;
a second electrode disposed on a side of the light-emitting stacked layer away from the first electrode, the second electrode being configured to be connected to a driving backplane; and
a passivation layer including a first passivation portion and a second passivation portion that are connected, wherein the first passivation portion covers a surface of the light-emitting stacked layer away from the first electrode; the first passivation portion is provided therein with a first via hole, and the second electrode is connected to the light-emitting stacked layer through the first via hole; and the second passivation portion covers at least part of sidewalls of the light-emitting stacked layer and the electrode body.

14. The light-emitting device according to claim 13, wherein the plurality of bonding protrusions are arranged in an array.

15. A light-emitting substrate, comprising:
a plurality of light-emitting devices according to claim 1; and
the driving backplane provided therein with a plurality of third electrodes, wherein the second electrode of the light-emitting device is connected to a third electrode of the driving backplane.

16. (canceled)

17. (canceled)

18. The light-emitting substrate according to claim 15, wherein the light-emitting substrate has a light-emitting region and a peripheral region, and further comprises:
a planar electrode covering the light-emitting region and extending to the peripheral region, wherein the planar electrode is disposed on a side of the light-emitting device away from the driving backplane and connected to the first electrode of the light-emitting device;
a plurality of encapsulation portions arranged at intervals on a side of the planar electrode away from the driving backplane, wherein an orthogonal projection of a single light-emitting device on the driving backplane is located within an orthogonal projection of a single encapsulation portion on the driving backplane; and
an auxiliary electrode disposed on the side of the planar electrode away from the driving backplane and connected to the planar electrode, wherein the auxiliary electrode is provided therein with a plurality of openings, a single opening exposes a single light-emitting device, and a shape of an orthogonal projection of the opening on the driving backplane is the same as a shape of the orthogonal projection of the light-emitting device on the driving backplane.

19. A backlight module, comprising:
the light-emitting substrate according to claim 15, the light-emitting substrate having a light-exit side and a non-light-exit side that are opposite to each other; and
a plurality of optical films disposed on the light-exit side of the light-emitting substrate.

20. A display apparatus, comprising: the backlight module according to claim 19; and
a display panel disposed on a side of the plurality of optical films in the backlight module away from the light-emitting substrate.

21-34. (canceled)

35. A light-emitting substrate, comprising:
a plurality of light-emitting devices according to claim 10; and
the driving backplane provided therein with a plurality of third electrodes, wherein the second electrode of the light-emitting device is connected to a third electrode of the driving backplane;
wherein among at least two adjacent light-emitting devices, one is a first light-emitting device and another is a second light-emitting device;
in the second light-emitting device, the second passivation portion is located on an edge portion of the first electrode that exceeds the light-emitting stacked layer, and an outer boundary of the second passivation portion is retracted relative to the boundary of the first electrode;
each of the first light-emitting device and the second light-emitting device includes a reflective layer, and the reflective layer is disposed on a side of the passivation layer away from the light-emitting stacked layer; a first sub-portion of the second light-emitting device faces the first light-emitting device; the reflective layer of the second light-emitting device covers the first sub-portion, and is connected to a portion of the first electrode of the first light-emitting device that exceeds the passivation layer.

36. A light-emitting substrate, comprising:
a plurality of light-emitting devices according to claim 10; and
the driving backplane provided therein with a plurality of third electrodes, wherein the second electrode of the light-emitting device is connected to a third electrode of the driving backplane;
wherein among at least two adjacent light-emitting devices, one is a third light-emitting device and another is a fourth light-emitting device;
in the fourth light-emitting device, the second passivation portion is located on an edge portion of the first electrode that exceeds the light-emitting stacked layer, and an outer boundary of the second passivation portion is retracted relative to the boundary of the first electrode;
the light-emitting substrate further comprises: a first planarization layer disposed on a side of the second electrode close to the light-emitting stacked layer of the light-emitting device, wherein the first planarization layer is provided therein with a third via hole, and the second electrode of the third light-emitting device is connected to a portion of the first electrode of the fourth light-emitting device that exceeds the passivation layer through the third via hole.
